(19) United States
(12) Patent Application Publication
(10) Pub. No.: US 2017/0039793 A1
(43) Pub. Date: Feb. 9, 2017

(54) VERIFICATION DEVICE, VERIFICATION SYSTEM AND METHOD FOR VERIFYING THE IDENTITY OF AN ARTICLE

(71) Applicant: BASF SE, Ludwigshafen (DE)

(72) Inventors: Robert SEND, Karlsruhe (DE); Ingmar BRUDER, Neuleiningen (DE); Stephan IRLE, Siegen (DE); Erwin THIEL, Siegen (DE)

(73) Assignee: BASF SE, Ludwigshafen (DE)

(21) Appl. No.: 15/304,328

(22) PCT Filed: Apr. 16, 2015
(86) PCT No.: PCT/IB2015/052769

§ 371 Date: Oct. 14, 2016

(30) Foreign Application Priority Data
Apr. 17, 2014 (EP) 14165144.8

(51) Int. Cl. G07D 7/12; H01G 9/20; H01L 51/42; B42D 25/21; B42D 25/378

(52) U.S. Cl. CPC G07D 7/12; B42D 25/21; B42D 25/378; H01L 51/42; H01G 9/2059

(57) ABSTRACT

A verification device (110) for verifying the identity of an article (114) is disclosed. The verification device (110) comprises: at least one illumination source (116) for illuminating at least one safety mark (124) of the article (114) with at least one light beam (122); at least one detector (118) adapted for detecting after an interaction of the light beam (122) with the safety mark (124), the detector (118) having at least one optical sensor (128), wherein the optical sensor (128) has at least one sensor region (130), wherein the optical sensor (128) is designed to generate at least one sensor signal in a manner dependent on an illumination of the sensor region (130) by the light beam (122), wherein the sensor signal, given the same total power of the illumination, is dependent on a beam cross-section of the light beam (122) in the sensor region (130); and at least one evaluation device (120) adapted for evaluating the sensor signal and for verifying the identity of the article (114) on the basis of the sensor signal. Further, a verification system (112), a method for verifying the identity of an article (114) and a use of an optical sensor (128) for verifying the identity of an article (114) are disclosed.

### FIELD OF THE INVENTION

The invention relates to a verification device, a verification system and a method for verifying the identity of at least one article. The invention further relates to a use of an optical sensor for verifying the identity of an article. The devices, the method and the use according to the present invention specifically may be employed in the field of identifying articles related to the transfer of money, such as credit cards or bills, and/or in the field of authentication of articles, such as in the field of anti-counterfeiting and/or in the field of identification of pharmaceuticals. Many other applications are feasible.

### PRIOR ART

Identification and verification of articles is a technical challenge occurring in many fields of science, technology or daily life. The present invention, in the following, will mainly be explained in the context of verification of money-related articles such as pools or credit cards. It shall be noted, however, that verification techniques are generally required and used in many technical fields, such as in the fields of anti-counterfeiting and anti-product piracy, in the field of patent protected or proprietary articles, in the field of pharmaceuticals, in the field of customs control, in the field of packaging and logistics or other fields.

Generally, in case articles are specifically produced in large numbers, such as in the field of consumer products or bills, safety measures generally need to be inexpensive but hard to forge. Further, verification processes and technologies generally have to be performed at high speed, such as in production lines.

In the art of identification and verification of articles, a large number of verification technologies are known. Thus, as an example, barcodes or other optically readable identifiers are used, such as identifiers applied to an outer surface of the article itself or a packaging of the article. Further, holograms may be used as identifiers, and appropriate optical readout technologies may be applied. Additionally or alternatively, electronic identifiers may be used, such as RFID tags or other types of electronic identifiers.

In many cases, however, verification tags or identifiers are prone to counterfeiting and copying. Thus, barcodes may be copied rather easily by using simple copying or printing machines, specifically since many barcodes are standardized. Similarly, electronic identifiers such as RFID tags or identification chips may be copied electronically. Further, many technologies require expensive readout of verification devices, and safety measures often are bulky and hard to implement into small or flat articles.

With regard to suitable verification devices and detectors usable therein, a large number of sensors are known, depending on the verification technology. Thus, for electronic identifiers, suitable electronic readout devices are known such as RFID readers. In optical technologies, a plurality of optical sensors are used, such as photovoltaic devices or photodiodes.

A large number of optical sensors which can be based generally on the use of inorganic and/or organic sensor materials are known from the prior art. Examples of such sensors are disclosed in US 2007/0176165 A1, U.S. Pat. No. 6,995,445 B2, DE 2501124 A1, DE 3225372 A1 or else in numerous other prior art documents. To an increasing extent, in particular for cost reasons and for reasons of large-area processing, sensors comprising at least one organic sensor material are being used, as described for example in US 2007/0176165 A1. In particular, so-called dye solar cells are increasingly of importance here, which are described generally, for example in WO 2009/013282 A1.

Various types of detectors on the basis of such optical sensors are known. Such detectors can be embodied in diverse ways, depending on the respective purpose of use. Examples of such detectors are imaging devices, for example, cameras and/or microscopes. High-resolution confocal microscopes are known, for example, which can be used in particular in the field of medical technology and biology in order to examine biological samples with high optical resolution. Further examples of detectors for optically detecting at least one object are distance measuring devices based, for example, on propagation time methods of corresponding optical signals, for example laser pulses. Further examples of detectors for optically detecting objects are triangulation systems, by means of which distance measurements can likewise be carried out.

In WO 2012/110924 A1, the content of which is herewith included by reference, a detector for optically detecting at least one object is proposed. The detector comprises at least one optical sensor. The optical sensor has at least one sensor region. The optical sensor is designed to generate at least one sensor signal in a manner dependent on an illumination of the sensor region. The sensor signal, given the same total power of the illumination, is dependent on a geometry of the illumination, in particular on a beam cross section of the illumination on the sensor area. In the following, optical sensors exhibiting this effect of the sensor signal being dependent on the photon density or flux of an illuminating light beam, given the same total power of illumination such as the devices disclosed by WO 2012/110924 A1, are generally referred to as FiP devices, indicating that the sensor signal or photocurrent is dependent on the photon flux F, given the same total power P of illumination. The detector, as disclosed by WO 2012/110924 A1, furthermore has at least one evaluation device. The evaluation device is designed to generate at least one item of geometrical information from the sensor signal, in particular at least one item of geometrical information about the illumination and/or the object.

U.S. provisional applications 61/739,173, filed on Dec. 19, 2012, 61/749,964, filed on Jan. 8, 2013, and 61/867,169, filed on Aug. 19, 2013, and international patent application PCT/IB2013/061095, filed on Dec. 18, 2013, the full content of all of which is herewith included by reference, disclose a method and a detector for determining a position of at least one object, by using at least one transversal optical sensor and at least one longitudinal optical sensor. Again, specifically for the longitudinal optical sensor, one or more FiP sensors may be used. Further, specifically, the use of sensor stacks is disclosed in order to determine a longitudinal position of the object with a high degree of accuracy and without ambiguity.

Despite the advantages implied by the above-mentioned detectors and the optical sensors, there still remains a need for improved verification technologies. Thus, specifically, there remains a need for verification techniques which generally are cost-efficient, widely insusceptible to forgery and suitable for use in high throughput manufacturing.

### Problem Addressed by the Invention

It is therefore an object of the present invention to provide devices and methods which solve the above-mentioned technical challenges. Specifically, a verification device, a verification system and a method for verifying the identity of at least one article shall be disclosed which are cost-efficient, widely insusceptible to forgery and suitable for use in high throughput manufacturing.

### SUMMARY OF THE INVENTION

This problem is solved by the invention with the features of the independent claims. Advantageous developments of the invention, which can be realized individually or in combination, are presented in the dependent claims and/or in the following specification and detailed embodiments.

As used in the following, the terms “have”, “comprise” or “include” or any arbitrary grammatical variations thereof are used in a non-exclusive way. Thus, these terms may both refer to a situation in which, besides the feature introduced by these terms, no further features are present in the entity described in this context and to a situation in which one or more further features are present. As an example, the expressions “A has B”, “A comprises B” and “A includes B” may refer to a situation in which, besides B, no other element is present in A (i.e. a situation in which A solely and exclusively consists of B) and to a situation in which, besides B, one or more further elements are present in entity A, such as element C, elements C and D or even further elements. Further, it shall be noted that in case the expression “at least one” or the expression “one or more” are used in the claims or in the specification, characterizing the presence of at least one element or feature, these expressions in most cases will not be repeated in the following. Thus, in case an element of feature is characterized as being provided at least once in the following, the element or feature may be mentioned using the singular, despite the fact that a plurality of these features or elements may be provided.

Further, as used in the following, the terms “preferably”, “more preferably”, “particularly”, “more particularly”, “specifically”, “more specifically” or similar terms are used in conjunction with optional features, without restricting alternative possibilities. Thus, features introduced by these terms are optional features and are not intended to restrict the scope of the claims in any way. The invention may, as the skilled person will recognize, be performed by using alternative features. Similarly, features introduced by “in an embodiment of the invention” or similar expressions are intended to be optional features, without any restriction regarding alternative embodiments of the invention, without any restriction regarding the scope of the invention and without any restriction regarding the possibility of combining the features introduced in such a way with other optional or non-optional features of the invention.

In a first aspect of the present invention, a verification device for verifying the identity of an article is provided. As generally used herein, the term “verify” generally refers to the process of evaluating or proving that something exists or is true, or to the process of making certain that something is correct. Specifically, the process may imply evaluating or verifying at least one condition. Consequently, the term “verifying an identity of an article” generally refers to the process of one or more of evaluating the identity of the article, proving that an article has a specific identity or proving that the assumption that the article has a specific identity, is true or false. Further, the term “verification device” generally refers to a device which is adapted for performing the process of verification as defined above, specifically for performing at least one verification step. Similarly, as will be outlined in further detail below, a “verification system” generally is a system comprising one, two or more than two components, the components being adapted for interacting with each other, the system being adapted for performing the process of verification as defined above.

The article as used herein generally may be an arbitrary object or device. Specifically, as will be outlined in further detail below, the article may be an article used for billing or money transfer, such as a credit card and/or a bill. Additionally or alternatively, the article may be a pharmaceutical product. Further, the article may be a packaging adapted for receiving one or more objects. Therein, in the following, no difference will be made between the actual object or article to be packaged by the packaging and the packaging itself. Thus, the verification of the article may both refer to the verification of the packaging and/or to the verification of the object or optical enclosed therein.

The verification device comprises:
at least one illumination source for illuminating at least one safety mark of the article with at least one light beam;
at least one detector adapted for detecting after an interaction of the light beam with the safety mark, the detector having at least one optical sensor, wherein the optical sensor has at least one sensor region, wherein the optical sensor is designed to generate at least one sensor signal in a manner dependent on an illumination of the sensor region by the light beam, wherein the sensor signal, given the same total power of the illumination, is dependent on a beam cross-section of the light beam in the sensor region; and
at least one evaluation device adapted for evaluating the sensor signal and for verifying the identity of the article on the basis of the sensor signal.

As used herein, an “illumination source” generally refers to a device adapted for generating light, preferably for generating one or more light beams. Therein, “light” generally refers to electromagnetic radiation in one or more of the visible spectral range, the infrared spectral range or the ultraviolet spectral range. Therein, the visible spectral range generally refers to a wavelength range of 380 nm to 780 nm, the infrared spectral range generally refers to a wavelength range of 780 nm to 1 mm, more preferably to a wavelength range of 780 nm to 3.0 μm, and the ultraviolet spectral range refers to a wavelength range of 1 nm to 380 nm, more preferably to a wavelength range of 200 nm to 380 nm. Specifically, visible light may be used.

As further used herein, a “light beam” generally refers to a portion of light traveling into a predetermined direction. The light beam specifically may be a collimated light beam. Further, the light beam specifically may be a coherent light beam. The illumination source consequently may comprise an arbitrary light source adapted for generating one or more light beams. As an example, the illumination source may comprise at least one laser, such as one or more of a semiconductor laser, a solid state laser, a dye laser or a gas laser. As an example, one or more laser diodes may be used. Additionally or alternatively, the illumination source may comprise other types of light sources such as one or more of a light emitting diode (LED), a light bulb or a discharge lamp. Further, the illumination source may comprise one or more beam transfer devices, such as one or more beam shaping elements like one or more lenses or lens systems, such as for collimating and/or focusing the at least one light beam. The illumination source may be adapted for generating a single light beam or a plurality of light beams. The illumination source may be adapted for generating a light beam having a single color or a plurality of light beams having the same color or having different colors.

The term “illuminating” generally refers to the fact that the at least one light beam generated by the illumination source is directed onto the safety mark. Therein, the light beam may directly propagate to the safety mark. Alternatively, the light beam may be deflected or reflected before reaching the safety mark. Further, the light beam may be modified before reaching the safety mark, such as by using one or more optical devices, such as one or more optical devices selected from the group consisting of: a wavelength-selective such as a color filter; a lens or lens system; a diaphragm; a grating. The optical devices may be part of the verification device.

As further used herein, a “safety mark” generally is a device, an element or a component which may be implemented into the article and/or attached to the optical and/or which may be part of the optical and which allows for determining the identity of the article. Therein, the “identity” generally is or contains at least one arbitrary item of information characterizing the article. Specifically, the identity may contain an arbitrary item of information indicating one or more of: the nature of the article; the origin of the article; a number or identifier of the article; a composition of the article. Other types of items of information characterizing the article may be used. Specifically, the identity of the article may be a unique identity which uniquely characterizes the article and/or which uniquely distinguishes the article from all other articles of a plurality of articles or even all articles which exist. Thus, generally, the safety mark may be an identifier of the optical which includes information on the identity of the article.

The safety mark, as an example, may be an integral component of the article, such as a region of the article. Alternatively, the safety mark may be attached to the article, such as by implementing the safety mark as a sticker or label which may be attached to the article.

As further used herein, the term “interact” generally refers to the process of two elements or entities acting upon each other. Thus, an interaction of the light beam with the safety mark generally refers to the process of one or more photons of the light beam acting upon one or more parts of the safety mark or vice versa. The interaction of the light beam with the safety mark generally may imply one or more of: a transmission of the light beam or a part thereof through the safety mark or a part thereof; a reflection of the light beam or a part thereof by the safety mark or a part thereof; a diffraction; an elastic or inelastic scattering of the light beam or a part thereof by the safety mark or a part thereof; and absorption of the light beam or a part thereof by the safety mark or a part thereof; a focusing or a defocusing of the light beam or a part thereof by the safety mark or a part thereof; a change of color of the light beam or a part thereof by the safety mark or a part thereof; a change of polarization of the light beam or a part thereof by the safety mark or a part thereof. Other types of interaction are generally known and may be feasible.

The light beam, as an example, may be fully or partially transmitted through the safety mark or may be fully or partially reflected by the safety mark, before being detected by the at least one detector.

As used herein, a “detector” generally is a device adapted for one or more of recording, registering or monitoring one or more parameters, such as optical parameters, such as at an intensity of light. The detector generally may be adapted for generating one or more detector readout signals or readout information, such as in an electronic format which may be an analogue and/or a digital format.

The detector comprises at least one optical sensor. As used herein, an “optical sensor” generally refers to a device adapted for performing at least one optical measurement. The optical sensor has at least one sensor region, wherein the optical sensor is designed to generate at least one sensor signal in a manner dependent on an illumination of the sensor region by the light beam, wherein the sensor signal, given the same total power of the illumination, is dependent on a beam cross-section of the light beam in the sensor region. Thus, generally, the at least one optical sensor is or comprises at least one FiP sensor as disclosed in the prior art section above. For potential specific definitions, details or optional layer setups of the at least one optical sensor, reference may be made to one or more of the above-mentioned documents WO 2012/110924 A1, U.S. provisional applications 61/739,173, 61/749,964, and 61/867,169, and international patent application PCT/IB2013/061095, the full content of all of which is herewith included by reference. Specifically, for potential embodiments of the optical sensor, reference may be made to the embodiments of optical sensors disclosed in WO 2012/110924 A1 or the embodiments of the longitudinal optical sensors disclosed in U.S. provisional applications 61/739,173, 61/749,964, and 61/867,169, and international patent application PCT/IB2013/061095. It shall be noted, however, that other embodiments are feasible, as long as the above-mentioned FiP effect occurs. Further optional details of the optical sensor will be disclosed below.

As used herein, the term “sensor signal” generally refers to an arbitrary signal generated by the at least one optical sensor. The sensor signal, as an example, may be an electrical signal, such as a current and/or a voltage. As will be explained in further detail below, the optical sensor preferably comprises one or more dye-sensitized solar cells (DSCs), more preferably one or more solid dye-sensitized solar cells (sDSCs). In these devices, generally, the sensor signal specifically may be an electrical current such as a photocurrent and/or a secondary sensor signal derived thereof. The sensor signal may be a single sensor signal or may comprise a plurality of sensor signals, such as by providing a continuous sensor signal. Further, the sensor signal may be or may comprise one or both of an analogue signal or a digital signal. The optical sensor may further provide one or more primary sensor signals which, optionally, may be transformed into one or more secondary sensor signals, by using appropriate signal processing. In the following and in the context of the present invention, both the primary sensor signal and the secondary sensor signal will be referred to as the “sensor signal”, non-withstanding the fact that both options still exist. A data processing or preprocessing, as an example, may comprise a filtering and/or an averaging.

The verification device further comprises at least one evaluation device adapted for evaluating the sensor signal and for verifying the identity of the article on the basis of the sensor signal. As used herein, the term “evaluation device” generally refers to an arbitrary device adapted to perform the named operations, preferably by using at least one data processing device and, more preferably, by using at least one processor. Thus, as an example, the at least one evaluation device may comprise at least one data processing device having a software code stored thereon comprising a number of computer commands. Additionally or alternatively, the evaluation device may comprise one or more of a measurement device or a signal processing device, such as for one or more of measuring, recording, preprocessing of processing the at least one sensor signal.

The evaluation device specifically may be adapted to determine at least one modification of at least one property of the light beam by evaluating the sensor signal, the modification being induced by the interaction of the light beam with the safety mark. As used herein, a “property” of the light beam generally refers to an arbitrary parameter or combination of parameters characterizing the light beam or a part thereof. As an example, the at least one property which is modified by the interaction with the safety mark may be selected from the group consisting of: a beam parameter of the light beam, preferably a beam parameter selected from the group consisting of a beam waist, a Rayleigh length, a focal position, a beam waist at a focal position, a Gaussian beam parameter; a polarization of the light beam; a spectral property of the light beam, preferably a color of the light beam and/or a wavelength of the light beam; a focusing or a defocusing of the light beam; a direction of propagation of the light beam. Thus, as an example, the safety mark may be adapted to focus or defocus the light beam or a part thereof during interaction with the light beam, such as during transmission of the light beam and/or during reflection of the light beam by the safety mark. Additionally or alternatively, the safety mark may be adapted to change polarization of the light beam or a part thereof during interaction of the light beam with the safety mark, such as during reflection of the light beam and/or transmission of the light beam by the safety mark. Again, additionally or alternatively, the safety mark may be adapted to change at least one color of the light beam during interaction with the light beam, such as during reflection of the light beam and/or during transmission of the light beam.

In an embodiment, the safety mark may be adapted to induce, by interaction with the light beam, modifications of at least two properties of the light beam. Thus, as an example, at least one first property might be modified, wherein the at least one first property and/or the modification there of preferably is detectable by the at least one optical sensor of the detector of the verification device. This at least one first property specifically may be a beam parameter of the light beam, preferably a beam parameter selected from the group consisting of a beam waist, a Rayleigh length, a focal position, a beam waist at a focal position, a Gaussian beam parameter. Still, additionally or alternatively, one or more of the other examples of beam parameters listed above may be modified. Additionally, optionally, at least one second property of the light beam might be modified by interaction with the safety mark, wherein the at least one second property preferably is visible by inspection, such as an inspection with the naked eye. As an example, the safety mark may be adapted to induce, by interaction with the light beam, a modification of one or more of the above-mentioned beam parameters of the light beam such as a beam geometry. Additionally, the safety mark may be adapted to induce a change in intensity, color or spectral composition of the light beam and/or of ambient light. Thus, as an example, the safety mark may be adapted to provide a visible safety feature, visible to the user, preferably with the naked eye, such as color effects, change in intensity, fluorescence, reflectance, scattering effects or even holographic effects or combinations thereof. Thereby, a combination of safety features may be provided, wherein at least one safety feature consists in a modification of the light beam which is detectable by the detector and at least one further modification of the light beam and/or of ambient light which is detectable by the naked eye.

The evaluation device, in order to verify the identity of the optical on the basis of the at least one sensor signal, specifically may be adapted to compare the modification of the at least one property of the light beam with at least one predetermined modification. Therein, the modification may be derived from the sensor signal or, equivalently, the sensor signal may directly be compared with at least one predetermined sensor signal corresponding to the predetermined modification. In the following, no difference will be made between these two equivalent possibilities. Generally, the evaluation device may be adapted to verify the identity of the article in case the modification corresponds to the predetermined modification and to deny a verification of the identity of the optical in case the modification fails to correspond to the predetermined modification.

The predetermined modification (or, equivalently, a predetermined sensor signal corresponding to the predetermined modification) may be predetermined by providing the predetermined modification in a data storage device. Additionally or alternatively, the at least one predetermined modification may be provided by other means, such as by at least one external device. Thus, the at least one predetermined modification or a corresponding sensor signal may be provided via at least one interface, such as from an external device, an external computer, an external network or a user. As an example, the evaluation device may be adapted to retrieve the at least one predetermined modification from at least one of a data storage device or a data transfer via at least one electronic interface. As an example, the evaluation device may be adapted to retrieve the at least one predetermined modification and/or at least one predetermined signal corresponding to the at least one predetermined modification from at least one remote database, such as via a wirebound and/or wireless data transfer.

As outlined above, at least one safety mark may be adapted to interact with the at least one light beam in various ways. Thus, as an example, the at least one property of the light beam modified by the interaction with the safety mark may be selected from the group consisting of: a beam parameter of the light beam, preferably a beam parameter selected from the group consisting of a beam waist, a Rayleigh length, a focal position, a beam waist at a focal position, a Gaussian beam parameter; a polarization of the light beam; a spectral property of the light beam, preferably a color of the light beam and/or a wavelength of the light beam; a focusing or a defocusing of the light beam; a direction of propagation of the light beam.

Specifically, the evaluation device may be adapted to determine a beam cross-section of the light beam in the sensor region by evaluating the sensor signal and by taking into account known beam properties of the light beam. The evaluation device specifically may be adapted to determine a change of the beam cross-section of the light beam induced by the interaction with the safety mark. Thus, as an example, the evaluation device may be adapted to compare a beam cross-section or a beam diameter or a sensor signal with at least one predetermined beam cross-section or predetermined beam diameter or predetermined sensor signal.

For evaluating the at least one sensor signal and for verifying the identity of the article on the basis of the at least one sensor signal, the evaluation device, as an example, may use a known correlation between the at least one sensor signal and at least one modification of at least one property of the light beam by the at least one safety mark. As an example, the evaluation device may use a known or predetermined correlation between the at least one sensor signal and a position of a focal point of the light beam after interaction with the safety mark, wherein the focal point and/or other beam parameters may be changed due to the interaction with the safety mark. Examples of correlations are a correlation of a sensor signal and a position of a focal point, such as the curves indicating a correlation between a sensor signal and a distance for typical FiP sensors as given in WO 2012/110924 A1. Correlations of this type may also be used in the context of the present invention for evaluating the at least one sensor signal and for verifying the identity of the article on the basis of the sensor signal. Thus, for each safety mark, a specific and unique shift of the focal position of the light beam may occur. On the basis of the at least one sensor signal, the shift of the focal position or the focal position itself may be measured and may be used for verifying the identity of the optical. Thus, as an example, a lookup table implementing the focal position of the change of focal position as one parameter and the identity of the article as a second parameter may be used. Other types of correlations are feasible. Further, as will be outlined in detail below, potential ambiguities in the correlation, such as ambiguities occurring at a distance before and after a focal point of the light beam, may be resolved by using a stack of optical sensors.

The evaluation device, as outlined above, may be adapted to determine a beam cross-section of the light beam in the sensor region by evaluating the sensor signal and by taking into account known beam properties of the light beam, thereby deriving the focal position and/or other beam parameters. Thereby, using a correlation between the at least one beam parameter derived thereof and the identity of the article, a verification of the identity of the optical may be performed. Additionally or alternatively, a more general correlation between the sensor signal and the identity of the article may be used, such as the above-mentioned correlation. The evaluation device may be adapted to perform an evaluation algorithm and/or may be adapted to use the above-mentioned correlation, such as by providing a lookup table implementing that correlation, in order to derive the identity of the optical and/or in order to verify the identity of the article.

As will be outlined in further detail below, the verification device may further comprise at least one modulation device for modulating at least one property of the light beam, preferably for periodically modulating an intensity of light beam. Thus, the verification device may be adapted to modulate intensity and/or a phase of the light beam, before and/or after interaction with the safety mark, such as periodically. Examples of modulation devices which may be used within the present invention will be given in further detail below.

As outlined above, the at least one optical sensor may be or may comprise at least one FiP sensor. For potential embodiments of these sensors, reference may be made to one or more of the prior art documents listed above or to one or more of the embodiments described in further detail below. Specifically, the at least one optical sensor may be or may comprise an organic photodetector, preferably an organic solar cell, more preferably a dye-sensitized organic solar cell and most preferably a solid dye-sensitized organic solar cell. The at least one optical sensor specifically may be or may comprise at least one photosensitive layer setup, the photosensitive layer setup having at least one first electrode, at least one second electrode and at least one photovoltaic material sandwiched in between the first electrode and the second electrode, wherein the photovoltaic material comprises at least one organic material. The photosensitive layer setup specifically may comprise, preferably in the given order, an n-semiconducting metal oxide, preferably a nano-porous n-semiconducting metal oxide, wherein the photosensitive layer setup further comprises at least one solid p-semiconducting organic material deposited on top of the n-semiconducting metal oxide. The n-semiconducting metal oxide specifically may be sensitized by using at least one dye. For potential embodiments of these materials, reference may be made to the above-mentioned prior art documents or to one or more of the embodiments given in further detail below. At least one of the first electrode or the second electrode may fully or partially be transparent. The at least one optical sensor may be or may comprise an opaque optical sensor and/or may be or may comprise at least one transparent or at least partially transparent optical sensor. In the latter case, preferably, both the first electrode and the second electrode may be at least partially transparent.

The at least one optical sensor specifically may be a large area optical sensor, without pixelation or subdivision of the optical sensor into pixels. Thus, the sensor region, as an example, may be a continuous sensor region providing a uniform sensor signal. The sensor region specifically may have a surface area of at least 1 mm², preferably of at least 5 mm², more preferably of at least 10 mm². Still, alternatively, a pixelation of the at least one optical sensor is feasible. Further, in addition to the at least one optical sensor, other sensors may be used, such as one or more imaging devices, such as CCD chips and/or CMOS chips. Thus, generally, the verification device may comprise one or more imaging devices, such as one or more pixelated devices like one or more CCD chips and/or one or more CMOS chips. By using the at least one pixelated device, and/or by using another type of additional transversal sensor, the verification device and, specifically, the detector may be adapted for determining a transversal position of the at least one light beam, such as e.g. disclosed in international patent application PCT/IB2013/061095, filed on Dec. 18, 2013, the full content of all of which is herewith included by reference.

The detector, as outlined above, may optionally further comprise at least one transfer device adapted for transferring the light beam to the at least one optical sensor. The transfer device preferably may be positioned in a light path inbetween the illumination source and the article and/or in a light path in between the article and the at least one optical sensor. As used herein, a “transfer device” generally is an arbitrary optical element adapted to guide the light beam onto the optical sensor. The guiding may take place with unmodified properties of the light beam or may take place with imaging or modifying properties. Thus, generally, the transfer device might have imaging properties and/or beam-shaping properties, i.e. might change a beam waist and/or a widening angle of the light beam and/or a shape of the cross-section of the light beam when the light beam passes the transfer device. The transfer device, as an example, may comprise one or more elements selected from the group consisting of a lens and a mirror. The mirror may be selected from the group consisting of a planar mirror, a convex mirror and a concave mirror. Additionally or alternatively, one or more prisms may be comprised. Additionally or alternatively, one or more wavelength-selective elements may be comprised, such as one or more filters, specifically color filters, and/or one or more dichroitic mirrors. Again, additionally or alternatively, the transfer device may comprise one or more diaphragms, such as one or more pinhole diaphragms and/or iris diaphragms.

The transfer device can, for example, comprise one or a plurality of mirrors and/or beam splitters and/or beam deflecting elements in order to influence a direction of the light beam or the light beam. Alternatively or additionally, the transfer device can comprise one or a plurality of imaging elements which can have the effect of a converging lens and/or a diverging lens. By way of example, the optional transfer device can have one or a plurality of lenses or lens systems and/or one or a plurality of convex and/or concave mirrors. Once again alternatively or additionally, the transfer device can have at least one wavelength-selective element, for example at least one optical filter. Once again, alternatively or additionally, the transfer device can be designed to impress a predefined beam profile on the electromagnetic radiation, for example, at the location of the sensor region and in particular the sensor area. The above-mentioned optional embodiments of the optional transfer device can, in principle, be realized individually or in any desired combination. The at least one transfer device, as an example, may be positioned in front of the detector, i.e. on a side of the detector facing towards the object. Additionally or alternatively, the transfer device may fully or partially be integrated into the illumination source.

The detector may comprise one, two, three or more than three optical sensors. Specifically, as outlined above, the detector may comprise a stack of at least two optical sensors. The stack may be arranged such that photosensitive areas of the sensor regions are oriented in a parallel fashion and, as an example, are oriented perpendicular to an optical axis of the detector. Specifically, the stack may comprise a plurality of large area optical sensors, i.e. optical sensors having a single sensor region only. The optical sensors of the stack may be identical or may differ with regard to one or more parameters. Thus, the optical sensors may specifically have one and the same spectral sensitivity or may have differing spectral sensitivities. For potential embodiments of a stack of optical sensors which may be used in the context of the present invention, reference may be made to one or more of WO 2012/110924 A1, U.S. provisional applications No. 61/739,173, No. 61/749,964, or No. 61/867,169, or international patent application PCT/IB2013/061095.

Generally, and specifically in case a stack of optical sensors is used, preferably, one or more of the optical sensors may be fully or partially transparent. Thus, the optical sensors may provide sufficient transparency for a light beam to fully or partially penetrate one optical sensor in order to reach one or more subsequent optical sensors. Thus, as an example, all optical sensors may fully or partially be transparent, except for the last optical sensor of the stack, which may be transparent or intransparent. As outlined above, for generating a transparent optical sensor, a layer setup may be used having a transparent first electrode and a transparent second electrode.

In case a stack of optical sensors is used, the sensor signals of the optical sensors may be used for various purposes. Again, as an example for the purposes the stack may be used for, reference may be made to U.S. provisional applications No. 61/739,173, No. 61/749,964, or No. 61/867,169, or international patent application PCT/IB2013/061095. Other purposes are feasible. Generally, the evaluation device may be adapted to evaluate at least the sensor signals generated by at least two of the optical sensors of the stack. Specifically, the evaluation device may be adapted to derive at least one beam parameter from the at least two sensor signals generated by the at least two optical sensors of the stack. Thus, a “beam parameter” as used herein generally refers to an arbitrary parameter or combination of parameters characterizing the light beam. As an example, at least one Gaussian beam parameter may be used, such as the minimum beam waist w₀ and/or the Raleigh length z. Other beam parameters are feasible. By using a stack of sensors and by evaluating the sensor signals of the stack, as an example, the above-mentioned ambiguity may be resolved which resides in the fact that a beam waist and equal distances before and after a focal point are identical. By measuring the beam waists at more than one position along an axis of propagation of the light beam, the ambiguity may be resolved, such as by comparing the beam waists. A widening beam waist indicates that the measurements were taken after the focal point, whereas a narrowing beam waist indicates that the measurements were taken before the focal point.

As outlined above, the illumination source preferably is adapted to produce a coherent light beam. Thus, the illumination source preferably may contain one or more coherent light sources. Thus, as an example, one or more lasers may be used, such as semiconductor lasers. Consequently, the illumination source may comprise at least one laser.

The illumination source may be adapted to generate one light beam or several light beams. In case several light beams are produced, the several light beams may have identical or differing spectral properties. As an example, the illumination source may be adapted to generate at least two different light beams having different colors. The detector may be adapted for distinguishing light beams having different colors. Thus, as an example, for detection and distinguishing of light beams having different colors, color filters or other wavelength sensitive elements may be used. Additionally or alternatively, as outlined above, different types of optical sensors may be used. By comparing sensor signals generated by optical sensors having differing spectral sensitivities, color information may be retrieved from the sensor signals. Thus, generally, the detector may comprise at least two optical sensors having differing spectral sensitivities. The differing spectral sensitivities, as an example, may be generated by using different types of dyes. Thus, as an example, a first type of optical sensors may be used having a first dye with a first absorption spectrum, and at least one second type of optical sensors may be used, having a second dye with a second absorption spectrum differing from the first absorption spectrum. By comparing the sensor signals of these two types of sensors, color information may be generated. Again, reference may be made to international patent application PCT/IB2013/061095 for potential embodiments.

The verification device generally may be implemented or may comprise a large number of devices or machines for various purposes. As outlined above, a possible specific application of the verification device is in the field of money transfer and authentication of credit cards. Thus, specifically, the verification device may comprise at least one of: a cashbox; a vending machine; an automated teller machine (ATM). Alternatively, the verification device may be implemented into one or more of these devices. Still, many other applications are feasible.

In a further aspect of the present invention, a verification system for verifying the identity of an article is disclosed. The verification system comprises at least one verification device according to the present invention, such as according to any one of the embodiments disclosed above or disclosed in further detail below. The verification system further comprises at least one article. The at least one article has at least one safety mark. The safety mark is adapted for interacting with the at least one light beam.

The safety mark is adapted for modifying at least one property of the light beam when interacting with the light beam. For this purpose, the safety mark may comprise one or more materials and/or one or more devices adapted for modifying the at least one property of the light beam. Thus, the safety mark may comprise at least one element selected from the group consisting of: an element adapted for modifying at least one beam parameter of the light beam, preferably a beam parameter selected from the group consisting of a beam waist, a Rayleigh length, a focal position, a beam waist at a focal position, a Gaussian beam parameter; a lens or lens system, preferably a Fresnel lens; a polarizer; a grating; an element for changing at least one spectral property of the light beam, preferably at least one element selected from the group consisting of a color filter and a wavelength-selective reflective element; an element for changing a direction of propagation of the light beam, preferably a reflective element. Various other elements or materials adapted for modifying at least one property of the light beam are known and may be used within the safety mark. Most preferably, however, the safety mark comprises at least one focusing element and/or at least one defocusing element, adapted for focusing or a defocusing the light beam and/or adapted for changing a focal position of the light beam, i.e. a position in which the light beam is focused. Thus, preference is due to the fact that, by using one or more FiP sensors for the at least one optical sensor, a change in the focal position of the light beam may easily be detected.

The safety mark may generally be one of a reflective safety mark and a transmissive safety mark. Thus, when interacting with the safety mark, the light beam may fully or partially be reflected by the safety mark and/or may fully or partially pass through the safety mark.

As outlined above, the verification system generally may comprise one or more transfer devices. The at least one transfer device may fully or partially be located in a beam path in front of the article or behind the article. Specifically, the at least one illumination source may comprise at least one transfer device adapted for focusing the light beam onto the safety mark.

One or more safety marks may be provided within the article and/or on the article. The safety mark may be adapted for changing at least one beam property of the light beam as a whole or of the light beam in part. The safety mark may be adapted to subdivide the light beam into at least two partial light beams. The partial light beams may have differing beam propagation properties, preferably different focal points. Thus, generally, the safety mark may be adapted for physically or virtually dividing the light beam into different parts of portions and for modifying these different parts of portions in a different way. Thus, generally, the safety mark may be adapted for generating a two-dimensional pattern or structure within the light beam after interaction, such as in a plane perpendicular to a direction of propagation of the light beam. Thus, generally, the safety mark may be adapted for generating a two-dimensional structure within the light beam. The detector may be adapted to at least partially determine the two-dimensional structure, such as by using appropriate spatially resolving means like imaging devices. For generating the two-dimensional structure or pattern, the safety mark may comprise at least two lenses having different focal lengths. In planar articles or planar safety marks, preferably, Fresnel lenses may be used for providing at least two lenses having different focal lengths. Still, other means are feasible.

The at least one safety mark and the at least one verification principle using the above-mentioned FiP sensor may be used as the sole means for verifying the identity of the article or may be used in combination with one or more other verification means. Thus, generally, the verification device and/or the verification system may comprise one or more additional devices for verifying the identity of the article. Thus, as an example, the article may further comprise at least one additional identifier. The detector may be adapted for reading out at least one item of verification information from the identifier. For this purpose, the detector may comprise at least one readout device for reading out the identifier, depending on the nature of the identifier, such as by using an optical readout device and/or a wireless or wire-bound readout device. The evaluation device may be adapted to use the at least one item of verification information during verifying the identity of the article. Thus, as an example, the evaluation device may be adapted to compare the at least one item of verification information with the at least one sensor signal and/or with at least one item of information derived thereof. As an example, the at least one item of verification information may correspond to a specific beam property or to a specific modification of a beam property of the light beam by the safety mark and, thus, may determine the above-mentioned predetermined sensor signal or predetermined modification. The evaluation device may be adapted to compare this predetermined sensor signal or predetermined modification with an actual sensor signal of the at least one optical sensor or an actual modification derived thereof, in order to verify the identity of the article. Thus, as an example, the at least one item of verification information may, as a clear version or in an encoded form, describe at least one predetermined focal position of the light beam, and the evaluation device may be adapted for deriving the actual focal position from the sensor signal and for comparing the actual focal position with the predetermined focal position. Generally, independent from the actual beam parameter or modification used in the process, in case a deviation of the predetermined value from the actual value or vice versa is detected, such as a deviation by more than a tolerance value, the identification may lead to a negative result, whereas otherwise the identification may lead to a positive result. Still, many other processes are feasible.

In case at least one additional identifier is used, the at least one additional identifier generally may fully or partially be implemented into the optical and/or may fully or partially be attached to the article. As an example, again, one or more chips, tags and/or labels may be used. The at least one additional identifier specifically may comprise at least one of an optically readable identifier and an electronically readable identifier. As an example, one or more optically readable identifiers may be implemented by using one or more barcodes. Additionally or alternatively, one or more electronically readable identifiers, such as identifiers readable wirelessly or contactlessly or readably via contact or in a wire-bound fashion, may be implemented by using one or more rapid frequency identification chips (RFIDs), such as implemented into one or more RFID tags.

As outlined above, the verification system may be used for various purposes. Without restricting the possibility of further applications, the article specifically may be selected from the group consisting of: an article used for payment, preferably a credit card and/or a bill; an ID card; a pharmaceutical; a packaging.

Further aspects referred to the above-mentioned embodiments of the safety mark. Thus, as outlined above, the safety mark preferably is adapted for modifying at least one beam parameter of the light beam. Thus, generally, the safety mark is adapted to modify at least one property of the light beam, wherein the at least one property and/or the modification thereof is detectable by the detector of the verification device. Additionally, however, the safety mark may provide one or more visible effects which are detectable by direct optical inspection, such as by inspection with the naked eye. Thus, as an example, the safety mark may comprise at least one visible feature, preferably at least one feature visible with the naked eye, more preferably one or more of a color filter, a hologram, a reflective element, an element adapted for changing an intensity of the light beam, of an additional light beam or of ambient light.

Thereby, generally, a user may determine, with the naked eye, if the safety mark is valid. The safety mark may be adapted to change at least one beam property such as at least one beam geometry of the light beam, which is barely visible with the naked eye. Additionally, the safety mark may be adapted to provide at least one visible feature, such as a feature implying color, intensity or reflective effects. Thereby, an additional safety feature may be provided, and the user may, by inspection with the naked eye, determine the validity of the safety mark. A more thorough evaluation may take place by using the detector.

In a further aspect of the present invention, a method for verifying the identity of an article is disclosed. The method comprises the following method steps which may be performed in the given order or in a different order. Further, two or more or even all of the method steps may be performed sequentially or at least partially simultaneously. Further, one, two or more or even all of the method steps may be performed once or repeatedly. The method may further comprise additional method steps. The method steps comprised by the method are as follows:
illuminating at least one safety mark of the article with at least one light beam by using at least one illumination source;
detecting the light beam after an interaction of the light beam with the safety mark by using a detector, the detector having at least one optical sensor, wherein the optical sensor has at least one sensor region, wherein the optical sensor is designed to generate at least one sensor signal in a manner dependent on an illumination of the sensor region by the light beam, wherein the sensor signal, given the same total power of the illumination, is dependent on a beam cross-section of the light beam in the sensor region; and
evaluating the sensor signal and verifying the identity of the article on the basis of the sensor signal, by using at least one evaluation device.

For further details, definitions or potential embodiments, reference may be made to the verification device and the verification system as disclosed above or as disclosed in further detail below. Thus, specifically, the method may imply using the verification device and/or the verification system according to the present invention, such as in one or more of the embodiments disclosed above or disclosed in further detail below.

In a further aspect of the present invention, a use of an optical sensor for verifying the identity of an article is disclosed. Therein, the optical sensor has at least one sensor region, wherein the optical sensor is designed to generate at least one sensor signal in a manner dependent on an illumination of the sensor region by a light beam, wherein the sensor signal, given the same total power of the illumination, is dependent on a beam cross-section of the light beam in the sensor region. Thus, generally, the use of a FiP sensor for verifying the identity of an article is proposed. Specifically, the optical sensor may be or may comprise at least one organic photodetector, preferably an organic solar cell, more preferably a dye-sensitized organic solar cell and most preferably a solid dye-sensitized organic solar cell. The optical sensor may comprise at least one photosensitive layer setup, the photosensitive layer setup preferably having at least one first electrode, at least one second electrode and at least one photovoltaic material sandwiched in between the first electrode and the second electrode, wherein the photovoltaic material may comprise at least one organic material. More specifically, the photosensitive layer setup may comprise an n-semiconducting metal oxide, preferably a nano-porous n-semiconducting metal oxide, wherein the photosensitive layer setup further may comprise at least one solid p-semiconducting organic material deposited on top of the n-semiconducting metal oxide. The n-semiconducting metal oxide may be sensitized by using at least one dye. At least one of the first electrode of the second electrode may be fully or partially transparent. For further details of the optical sensor, reference may be made to the embodiments given above or given in further detail below.

As an example, the optical sensor, in the verification device, the verification system, the method and the use according to the present invention, may comprise at least one substrate and at least one photosensitive layer setup disposed thereon. As used herein, the expression “substrate” generally refers to a carrier element providing mechanical stability to the optical sensor. As will be outlined in further detail below, the substrate may be a transparent substrate and/or an intransparent substrate. As an example, the substrate may be a plate-shaped substrate, such as a slide and/or a foil. The substrate generally may have a thickness of 100 μm to 5 mm, preferably a thickness of 500 μm to 2 mm. However, other thicknesses are feasible.

As further used herein, a “photosensitive layer” setup generally refers to an entity having two or more layers which, generally, has light-sensitive properties. Thus, the photosensitive layer setup is capable of converting light in one or more of the visible, the ultraviolet or the infrared spectral range into an electrical signal. For this purpose, a large number of physical and/or chemical effects may be used, such as photo effects and/or excitation of organic molecules and/or formation of excited species within the photosensitive layer setup.

The photosensitive layer setup may have at least one first electrode, at least one second electrode and at least one photovoltaic material sandwiched in between the first electrode and the second electrode. As will be outlined in further detail below, the photosensitive layer setup may be embodied such that the first electrode is closest to the substrate and, thus, is embodied as a bottom electrode. Alternatively, the second electrode may be closest to the substrate and, thus, may be embodied as a bottom electrode. Generally, the expressions “first” and “second”, as used herein, are used for identification purposes only, without intending any ranking and/or without intending to denote any order of the photosensitive layer setup. Generally, the term “electrode” refers to an element of the photosensitive layer setup capable of electrically contacting the at least one photovoltaic material sandwiched in between the electrodes. Thus, each electrode may provide one or more layers and/or fields of an electrically conductive material contacting the photovoltaic material. Additionally, each of the electrodes may provide additional electrical leads, such as one or more electrical leads for contacting the first electrode and/or the second electrode. Thus, each of the first and second electrodes may provide one or more contact pads for contacting the first electrode and/or the second electrode, respectively.

As used herein, a “photovoltaic material” generally is a material or a combination of materials providing the above-mentioned photosensitivity of the photosensitive layer setup. Thus, the photovoltaic material may provide one or more layers of material which, under illumination by light in one or more of the visible, the ultraviolet or the infrared spectral range, are capable of generating an electrical signal, preferably an electrical signal indicating an intensity of illumination. Thus, the photovoltaic material may comprise one or more photovoltaic material layers which, by itself or in combination, are capable of generating positive and/or negative charges in response to the illumination, such as electrons and/or holes. The photovoltaic material may comprise at least one organic material.

As used herein, the term “sandwiched” generally refers to the fact that the photovoltaic material, at least partially, is located in an intermediate space in between the first electrode and the second electrode, notwithstanding the fact that other regions of the photovoltaic material may exist, which are located outside the intermediate space in between the first electrode and the second electrode.

As outlined above, one of the first electrode and the second electrode may form a bottom electrode closest to the substrate, and the other one may form a top electrode facing away from the substrate. Further, the first electrode may be an anode of the photosensitive layer setup, and the second electrode may be a cathode of the photosensitive layer setup or vice versa.

Specifically, one of the first electrode and the second electrode may be a bottom electrode and the other of the first electrode and the second electrode may be a top electrode. The bottom electrode may be applied to the substrate directly or indirectly, wherein the latter e.g. may imply interposing one or more buffer layers or protection layers in between the bottom electrode and the substrate. The photovoltaic material may be applied to the bottom electrode and may at least partially cover the bottom electrode. As outlined above, one or more portions of the bottom electrode may remain uncovered by the at least one photovoltaic material, such as for contacting purposes. The top electrode may be applied to the photovoltaic material, such that one or more portions of the top electrode are located on top of the photovoltaic material. As further outlined above, one or more additional portions of the top electrode may be located elsewhere, such as for contacting purposes. Thus, as an example, the bottom electrode may comprise one or more contact pads, which remain uncovered by the photovoltaic material. Similarly, the top electrode may comprise one or more contact pads, wherein the contact pad preferably is located outside an area coated by the photovoltaic material.

As outlined above, the substrate may be intransparent or at least partially transparent. As used herein, the term “transparent” refers to the fact that in one or more of the visible spectral range, the ultraviolet spectral range or the infrared spectral range, light may penetrate the substrate at least partially. Thus, in one or more of the visible spectral range, the infrared spectral range or the ultraviolet spectral range, the substrate may have a transparency of at least 10%, preferably at least 30% or, more preferably, at least 50%. As an example, a glass substrate, a quartz substrate, a transparent plastic substrate or other types of substrates may be used as transparent substrates. Further, multi-layer substrates may be used, such as laminates.

As outlined above, one or both of the first electrode of the second electrode may be transparent. Thus, depending on the direction of illumination of the optical sensor, the bottom electrode, the top electrode or both may be transparent. As an example, in case a transparent substrate is used, preferably, at least the bottom electrode is a transparent electrode. In case the bottom electrode is the first electrode and/or in case the bottom electrode functions as an anode, preferably, the bottom electrode comprises at least one layer of a transparent conductive oxide, such as indium-tin-oxide, zinc oxide, fluorine-doped tin oxide or a combination of two or more of these materials. In case a transparent substrate and a transparent bottom electrode are used, a direction of illumination of the optical sensor may be through the substrate. In case an intransparent substrate is used, the bottom electrode may be transparent or intransparent. Thus, as an example, an intransparent electrode may comprise one or more metal layers of generally arbitrary thickness, such as one or more layers of silver and/or other metals. As an example, the bottom electrode and/or the first electrode may have a work function of 3 eV to 6 eV.

As outlined above, the top electrode may be intransparent or transparent. In case an illumination of the optical sensor takes place through the substrate and the bottom electrode, the top electrode may be intransparent. In case an illumination takes place through the top electrode, preferably, the top electrode is transparent. Still, as will be outlined in further detail below, the whole optical sensor may be transparent, at least in one or more spectral ranges of light. In this case, both the bottom electrode and the top electrode may be transparent.

In order to create a transparent top electrode, various techniques may be used. Thus, as an example, the top electrode may comprise a transparent conductive oxide, such as zinc oxide. The transparent conductive oxide may be applied, as an example, by using appropriate physical vapor deposition techniques, such as sputtering, thermal evaporation and/or electron-beam evaporation. The top electrode, preferably the second electrode, may be a cathode. Alternatively, the top electrode may as well function as an anode. Specifically in case the top electrode functions as a cathode, the top electrode preferably comprises one or more metal layers, such as metal layers having a work function of preferably less than 4.5 eV, such as aluminum. In order to create a transparent metal electrode, thin metal layers may be used, such as metal layers having a thickness of less than 50 nm, more preferably less than 40 nm or even more preferably less than 30 nm. Using these metal thicknesses, a transparency at least in the visible spectral range may be created. In order to still provide sufficient electrical conductivity, the top electrode may, in addition to the one or more metal layers, comprise additional electrically conductive layers, such as one or more electrically conductive organic materials applied in between the metal layers and the at least one photovoltaic material. Thus, as an example, one or more layers of an electrically conductive polymer may be interposed in between the metal layer of the top electrode and the photovoltaic material.

As outlined above, the top electrode may be intransparent or transparent. In case a transparent top electrode is provided, several techniques are applicable, as partially explained above. Thus, as an example, the top electrode may comprise one or more metal layers. The at least one metal layer may have a thickness of less than 50 nm, preferably a thickness of less than 40 nm, more preferably a thickness of less than 30 nm or even a thickness of less than 25 nm or less than 20 nm. The metal layer may comprise at least one metal selected from the group consisting of: Ag, Al, Au, Pt, Cu. Additionally or alternatively, other metals and/or combinations of metals, such as combinations of two or more of the named metals and/or other metals may be used. Further, one or more alloys may be used, containing two or more metals. As an example, one or more alloys of the group consisting of NiCr, AlNiCr, MoNb and AlNd may be used. The use of other metals, however, is possible.

The top electrode may further comprise at least one electrically conductive polymer embedded in between the photovoltaic material and the metal layer. Various possibilities of electrically conductive polymers which are usable within the present invention exist. Thus, as an example, the electrically conductive polymer may be intrinsically electrically conductive. As an example, the electrically conductive polymer may comprise one or more conjugated polymers. As an example, the electrically conductive polymer may comprise at least one polymer selected from the group consisting of a poly-3,4-ethylenedioxythiophene (PEDOT), preferably PEDOT being electrically doped with at least one counter ion, more preferably PEDOT doped with sodium polystyrene sulfonate (PEDOT:PSS); a polyaniline (PANI); a polythiophene.

The optical sensor may further comprise at least one encapsulation protecting one or more of the photovoltaic material, the first electrode or the second electrode at least partially from moisture. Thus, as an example, the encapsulation may comprise one or more encapsulation layers and/or may comprise one or more encapsulation caps. As an example, one or more caps selected from the group consisting of glass caps, metal caps, ceramic caps and polymer or plastic caps may be applied on top of the photosensitive layer setup in order to protect the photosensitive layer setup or at least a part thereof from moisture. Additionally or alternatively, one or more encapsulation layers may be applied, such as one or more organic and/or inorganic encapsulation layers. Still, contact pads for electrically contacting the bottom electrode and/or the top electrode may be located outside the cap and/or the one or more encapsulation layers, in order to allow for an appropriate electrical contacting of the electrodes.

As outlined above, the optical sensor or, in case a plurality of optical sensors is provided, at least one of the optical sensors may be embodied as a photovoltaic device, preferably an organic photovoltaic device. Thus, as an example, the optical sensor may form a dye-sensitized solar cell (DSC), more preferably a solid dye-sensitized solar cell (sDSC). Thus, as outlined above, the photovoltaic material preferably may comprise at least one n-semiconducting metal oxide, at least one dye and at least one solid p-semiconducting organic material. As further outlined above, the n-semiconducting metal oxide may be sub-divided into at least one dense layer or solid layer of the n-semiconducting metal oxide, functioning as a buffer layer on top of the first electrode. Additionally, the n-semiconducting metal oxide may comprise one or more additional layers of the same or another n-semiconducting metal oxide having nano-porous and/or nano-particulate properties. The dye may sensitize the latter layer, by forming a separate dye layer on top of the nano-porous n-semiconducting metal oxide and/or by soaking at least part of the n-semiconducting metal oxide layer. Thus, generally, the nano-porous n-semiconducting metal oxide may be sensitized with the at least one dye, preferably with the at least one organic dye.

Further, in case a stack comprising at least two optical sensors is used, the optical sensors may have the same spectral sensitivity and/or may have differing spectral sensitivities. Thus, as an example, one of the imaging devices may have a spectral sensitivity in a first wavelength band, and another one of the imaging devices may have a spectral sensitivity in a second wavelength band, the first wavelength band being different from the second wavelength band. By evaluating signals and/or images generated with these imaging devices, a color information may be generated. In this context, it is preferred to use at least one transparent optical sensor within the stack of imaging devices, as discussed above. The spectral sensitivities of the imaging devices may be adapted in various ways. Thus, the at least one photovoltaic material comprised in the imaging devices may be adapted to provide a specific spectral sensitivity, such as by using different types of dyes. Thus, by choosing appropriate dyes, a specific spectral sensitivity of the imaging devices may be generated. Additionally or alternatively, other means for adjusting the spectral sensitivity of the imaging devices may be used. Thus, as an example, one or more wavelength-selective elements may be used and may be assigned to one or more of the imaging devices, such that the one or more wavelength-selective elements, by definition, become part of the respective imaging devices. As an example, one or more wavelength-selective elements may be used selected from the group consisting of a filter, preferably a color filter, a prism and a dichroitic mirror. Thus, generally, by using one or more of the above-mentioned means and/or other means, the imaging devices may be adjusted such that two or more of the imaging devices exhibit differing spectral sensitivities.

In the following, examples of the photosensitive layer setup, specifically with regard to materials which may be used within this photosensitive layer setup, are disclosed. As outlined above, the photosensitive layer setup preferably is a photosensitive layer setup of a solar cell, more preferably an organic solar cell and/or a dye-sensitized solar cell (DSC), more preferably a solid dye-sensitized solar cell (sDSC). Other embodiments, however, are feasible.

As outlined above, preferably, the photosensitive layer setup comprises at least one photovoltaic material, such as at least one photovoltaic layer setup comprising at least two layers, sandwiched between the first electrode and the second electrode. Preferably, the photosensitive layer setup and the photovoltaic material comprise at least one layer of an n-semiconducting metal oxide, at least one dye and at least one p-semiconducting organic material. As an example, the photovoltaic material may comprise a layer setup having at least one dense layer of an n-semiconducting metal oxide such as titanium dioxide, at least one nano-porous layer of an n-semiconducting metal oxide contacting the dense layer of the n-semiconducting metal oxide, such as at least one nano-porous layer of titanium dioxide, at least one dye sensitizing the nano-porous layer of the n-semiconducting metal oxide, preferably an organic dye, and at least one layer of at least one p-semiconducting organic material, contacting the dye and/or the nano-porous layer of the n-semiconducting metal oxide.

The dense layer of the n-semiconducting metal oxide, as will be explained in further detail below, may form at least one barrier layer in between the first electrode and the at least one layer of the nano-porous n-semiconducting metal oxide. It shall be noted, however, that other embodiments are feasible, such as embodiments having other types of buffer layers.

The first electrode may be one of an anode or a cathode, preferably an anode. The second electrode may be the other one of an anode or a cathode, preferably a cathode. The first electrode preferably contacts the at least one layer of the n-semiconducting metal oxide, and the second electrode preferably contacts the at least one layer of the p-semiconducting organic material. The first electrode may be a bottom electrode, contacting a substrate, and the second electrode may be a top electrode facing away from the substrate. Alternatively, the second electrode may be a bottom electrode, contacting the substrate, and the first electrode may be the top electrode facing away from the substrate. Preferably, one or both of the first electrode and the second electrode are transparent.

In the following, some options regarding the first electrode, the second electrode and the photovoltaic material, preferably the layer setup comprising two or more photovoltaic materials, will be disclosed. It shall be noted, however, that other embodiments are feasible.

a) Substrate, First Electrode and n-Semiconductive Metal Oxide

Generally, for preferred embodiments of the first electrode and the n-semiconductive metal oxide, reference may be made to one or more of WO 2012/110924 A1, U.S. provisional applications No. 61/739,173, No. 61/749,964, or No. 61/867,169, or international patent application PCT/IB2013/061095, the full content of all of which is herewith included by reference. Other embodiments are feasible.

In the following, it shall be assumed that the first electrode is the bottom electrode directly or indirectly contacting the substrate. It shall be noted, however, that other setups are feasible, with the first electrode being the top electrode.

The n-semiconductive metal oxide which may be used in the photosensitive layer setup, such as in at least one dense film (also referred to as a solid film) of the n-semiconductive metal oxide and/or in at least one nano-porous film (also referred to as a nano-particulate film) of the n-semiconductive metal oxide, may be a single metal oxide or a mixture of different oxides. It is also possible to use mixed oxides. The n-semiconductive metal oxide may especially be porous and/or be used in the form of a nanoparticulate oxide, nanoparticles in this context being understood to mean particles which have an average particle size of less than 0.1 micrometer. A nanoparticulate oxide is typically applied to a conductive substrate (i.e. a carrier with a conductive layer as the first electrode) by a sintering process as a thin porous film with large surface area.

Preferably, the optical sensor uses at least one transparent substrate. However, setups using one or more intransparent substrates are feasible.

The substrate may be rigid or else flexible. Suitable substrates (also referred to hereinafter as carriers) are, as well as metal foils, in particular plastic sheets or films and especially glass sheets or glass films. Particularly suitable electrode materials, especially for the first electrode according to the above-described, preferred structure, are conductive materials, for example transparent conductive oxides (TCOs), for example fluorine- and/or indium-doped tin oxide (FTO or ITO) and/or aluminum-doped zinc oxide (AZO), carbon nanotubes or metal films. Alternatively or additionally, it would, however, also be possible to use thin metal films which still have a sufficient transparency. In case an intransparent first electrode is desired and used, thick metal films may be used.

The substrate can be covered or coated with these conductive materials. Since generally, only a single substrate is required in the structure proposed, the formation of flexible cells is also possible. This enables a multitude of end uses which would be achievable only with difficulty, if at all, with rigid substrates, for example use in bank cards, garments, etc.

The first electrode, especially the TCO layer, may additionally be covered or coated with a solid or dense metal oxide buffer layer (for example of thickness 10 to 200 nm), in order to prevent direct contact of the p-type semiconductor with the TCO layer (see Peng et al., Coord. Chem. Rev. 248, 1479 (2004)). The use of solid p-semiconducting electrolytes, in the case of which contact of the electrolyte with the first electrode is greatly reduced compared to liquid or gel-form electrolytes, however, makes this buffer layer unnecessary in many cases, such that it is possible in many cases to dispense with this layer, which also has a current-limiting effect and can also worsen the contact of the n-semiconducting metal oxide with the first electrode. This enhances the efficiency of the components. On the other hand, such a buffer layer can in turn be utilized in a controlled manner in order to match the current component of the dye solar cell to the current component of the organic solar cell. In addition, in the case of cells in which the buffer layer has been dispensed with, especially in solid cells, problems frequently occur with unwanted recombinations of charge carriers. In this respect, buffer layers are advantageous in many cases specifically in solid cells.

As is well known, thin layers or films of metal oxides are generally inexpensive solid semiconductor materials (n-type semiconductors), but the absorption thereof, due to large bandgaps, is typically not within the visible region of the electromagnetic spectrum, but rather usually in the ultraviolet spectral region. For use in solar cells, the metal oxides therefore generally, as is the case in the dye solar cells, have to be combined with a dye as a photosensitizer, which absorbs in the wavelength range of sunlight, i.e. at 300 to 2000 nm, and, in the electronically excited state, injects electrons into the conduction band of the semiconductor. With the aid of a solid p-type semiconductor used additionally in the cell as an electrolyte, which is in turn reduced at the counter electrode, electrons can be recycled to the sensitizer, such that it is regenerated.

Of particular interest for use in organic solar cells are the semiconductors zinc oxide, tin dioxide, titanium dioxide or mixtures of these metal oxides. The metal oxides can be used in the form of nanocrystalline porous layers. These layers have a large surface area which is coated with the dye as a sensitizer, such that a high absorption of sunlight is achieved. Metal oxide layers which are structured, for example nanorods, give advantages such as higher electron mobilities or improved pore filling by the dye.

The metal oxide semiconductors can be used alone or in the form of mixtures. It is also possible to coat a metal oxide with one or more other metal oxides. In addition, the metal oxides may also be applied as a coating to another semiconductor, for example GaP, ZnP or ZnS.

Particularly preferred semiconductors are zinc oxide and titanium dioxide in the anatase polymorph, which is preferably used in nanocrystalline form.

In addition, the sensitizers can advantageously be combined with all n-type semiconductors which typically find use in these solar cells. Preferred examples include metal oxides used in ceramics, such as titanium dioxide, zinc oxide, tin(IV) oxide, tungsten(VI) oxide, tantalum(V) oxide, niobium(V) oxide, cesium oxide, strontium titanate, zinc stannate, complex oxides of the perovskite type, for example barium titanate, and binary and ternary iron oxides, which may also be present in nanocrystalline or amorphous form.

Due to the strong absorption that customary organic dyes and ruthenium, phthalocyanines and porphyrins have, even thin layers or films of the n-semiconducting metal oxide are sufficient to absorb the required amount of dye. Thin metal oxide films in turn have the advantage that the probability of unwanted recombination processes falls and that the internal resistance of the dye subcell is reduced. For the n-semiconducting metal oxide, it is possible with preference to use layer thicknesses of 100 nm up to 20 micrometers, more preferably in the range between 500 nm and approx. 3 micrometers.

### b) Dye

In the context of the present invention, as usual in particular for DSCs, the terms “dye”, “sensitizer dye” and “sensitizer” are used essentially synonymously without any restriction of possible configurations. Numerous dyes which are usable in the context of the present invention are known from the prior art, and so, for possible material examples, reference may also be made to the above description of the prior art regarding dye solar cells. As a preferred example, one or more of the dyes disclosed in one or more of WO 2012/110924 A1, U.S. provisional applications No. 61/739,173, No. 61/749,964, or No. 61/867,169, or international patent application PCT/IB2013/061095, the full content of all of which is herewith included by reference. Additionally or alternatively, one or more of the dyes as disclosed in WO 2007/054470 A1 and/or WO 2012/085803 A1 may be used, the full content of which is included by reference, too.

Dye-sensitized solar cells based on titanium dioxide as a semiconductor material are described, for example, in U.S. Pat. No. 4,927,721, Nature 353, p. 737-740 (1991) and U.S. Pat. No. 5,350,644, and also Nature 395, p. 583-585 (1998) and EP-A-1 176 646. The dyes described in these documents can in principle also be used advantageously in the context of the present invention. These dye solar cells preferably comprise monomolecular films of transition metal complexes, especially ruthenium complexes, which are bonded to the titanium dioxide layer via acid groups as sensitizers.

Many sensitizers which have been proposed include metal-free organic dyes, which are likewise also usable in the context of the present invention. High efficiencies of more than 4%, especially in solid dye solar cells, can be achieved, for example, with indoline dyes (see, for example, Schmidt-Mende et al., Adv. Mater. 2005, 17, 813). U.S. Pat. No. 6,359,211 describes the use, also implementable in the context of the present invention, of cyanine, oxazine, thiazine and acridine dyes which have carboxyl groups bonded via an alkylene radical for fixing to the titanium dioxide semiconductor.

Particularly preferred sensitizer dyes in the dye solar cell proposed are the perylene derivatives, terrylene derivatives and quaterrylene derivatives described in DE 10 2005 053 995 A1 or WO 2007/054470 A1. Further, as outlined above, one or more of the dyes as disclosed in WO 2012/085803 A1 may be used. The use of these dyes, which is also possible in the context of the present invention, leads to photovoltaic elements with high efficiencies and simultaneously high stabilities.

The rylenes exhibit strong absorption in the wavelength range of sunlight and can, depending on the length of the conjugated system, cover a range from about 400 nm (perylene derivatives I from DE 10 2005 053 995 A1) up to about 900 nm (quaterrylene derivatives I from DE 10 2005 053 995 A1). Rylene derivatives I based on terrylene absorb, according to the composition thereof, in the solid state adsorbed onto titanium dioxide, within a range from about 400 to 800 nm. In order to achieve very substantial utilization of the incident sunlight from the visible into the near infrared region, it is advantageous to use mixtures of different rylene derivatives I. Occasionally, it may also be advisable to use different rylene homologs.

The rylene derivatives I can be fixed easily and in a permanent manner to the n-semiconducting metal oxide film. The bonding is effected via the anhydride function (x1) or the carboxyl groups —COOH or —COO— formed in situ, or via the acid groups A present in the imide or condensate radicals ((x2) or (x3)). The rylene derivatives I described in DE 10 2005 053 995 A1 have good suitability for use in dye-sensitized solar cells in the context of the present invention.

It is particularly preferred when the dyes, at one end of the molecule, have an anchor group which enables the fixing thereof to the n-type semiconductor film. At the other end of the molecule, the dyes preferably comprise electron donors Y which facilitate the regeneration of the dye after the electron release to the n-type semiconductor, and also prevent recombination with electrons already released to the semiconductor.

For further details regarding the possible selection of a suitable dye, it is possible, for example, again to refer to DE 10 2005 053 995 A1. By way of example, it is possible especially to use ruthenium complexes, porphyrins, other organic sensitizers, and preferably rylenes.

The dyes can be fixed onto or into the n-semiconducting metal oxide film, such as the nano-porous n-semiconducting metal oxide layer, in a simple manner. For example, the n-semiconducting metal oxide films can be contacted in the freshly sintered (still warm) state over a sufficient period (for example about 0.5 to 24 h) with a solution or suspension of the dye in a suitable organic solvent. This can be accomplished, for example, by immersing the metal oxide-coated substrate into the solution of the dye.

If combinations of different dyes are to be used, they may, for example, be applied successively from one or more solutions or suspensions which comprise one or more of the dyes. It is also possible to use two dyes which are separated by a layer of, for example, CuSCN (on this subject see, for example, Tennakone, K. J., Phys. Chem. B. 2003, 107, 13758). The most convenient method can be determined comparatively easily in the individual case.

In the selection of the dye and of the size of the oxide particles of the n-semiconducting metal oxide, the organic solar cell should be configured such that a maximum amount of light is absorbed. The oxide layers should be structured such that the solid p-type semiconductor can efficiently fill the pores. For instance, smaller particles have greater surface areas and are therefore capable of adsorbing a greater amount of dyes. On the other hand, larger particles generally have larger pores which enable better penetration through the p-conductor.

c) p-Semiconducting Organic Material

As described above, the at least one photosensitive layer setup, such as the photosensitive layer setup of the DSC or sDSC, can comprise in particular at least one p-semiconducting organic material, preferably at least one solid p-semiconducting material, which is also designated hereinafter as p-type semiconductor or p-type conductor. Hereinafter, a description is given of a series of preferred examples of such organic p-type semiconductors which can be used individually or else in any desired combination, for example in a combination of a plurality of layers with a respective p-type semiconductor, and/or in a combination of a plurality of p-type semiconductors in one layer.

In order to prevent recombination of the electrons in the n-semiconducting metal oxide with the solid p-conductor, it is possible to use, between the n-semiconducting metal oxide and the p-type semiconductor, at least one passivating layer which has a passivating material. This layer should be very thin and should as far as possible cover only the as yet uncovered sites of the n-semiconducting metal oxide. The passivation material may, under some circumstances, also be applied to the metal oxide before the dye. Preferred passivation materials are especially one or more of the following substances: Al₂O₃; silanes, for example CH₃SiCl₃; Al³+; 4-tert-butylpyridine (TBP); MgO; GBA (4-guanidinobutyric acid) and similar derivatives; alkyl acids; hexadecylmalonic acid (HDMA).

As described above, preferably one or more solid organic p-type semiconductors are used—alone or else in combination with one or more further p-type semiconductors which are organic or inorganic in nature. In the context of the present invention, a p-type semiconductor is generally understood to mean a material, especially an organic material, which is capable of conducting holes, that is to say positive charge carriers. More particularly, it may be an organic material with an extensive π-electron system which can be oxidized stably at least once, for example to form what is called a free-radical cation. For example, the p-type semiconductor may comprise at least one organic matrix material which has the properties mentioned. Furthermore, the p-type semiconductor can optionally comprise one or a plurality of dopants which intensify the p-semiconducting properties. A significant parameter influencing the selection of the p-type semiconductor is the hole mobility, since this partly determines the hole diffusion length (cf. Kumara, G., Langmuir, 2002, 18, 10493-10495). A comparison of charge carrier mobilities in different spiro compounds can be found, for example, in T. Saragi, Adv. Funct. Mater. 2006, 16, 966-974.

Preferably, in the context of the present invention, organic semiconductors are used (i.e. one or more of low molecular weight, oligomeric or polymeric semiconductors or mixtures of such semiconductors). Particular preference is given to p-type semiconductors which can be processed from a liquid phase. Examples here are p-type semiconductors based on polymers such as polythiophene and polyarylamines, or on amorphous, reversibly oxidizable, nonpolymeric organic compounds, such as the spirobifluorenes mentioned at the outset (cf., for example, US 2006/0049397 and the spiro compounds disclosed therein as p-type semiconductors, which are also usable in the context of the present invention). Preference is also given to using low molecular weight organic semiconductors, such as the low molecular weight p-type semiconducting materials as disclosed in WO 2012/110924 A1, preferably spiro-MeOTAD, and/or one or more of the p-type semiconducting materials disclosed in Leijtens et al., ACS Nano, VOL. 6, NO. 2, 1455-1462 (2012). In addition, reference may also be made to the remarks regarding the p-semiconducting materials and dopants from the above description of the prior art.

The p-type semiconductor is preferably producible or produced by applying at least one p-conducting organic material to at least one carrier element, wherein the application is effected for example by deposition from a liquid phase comprising the at least one p-conducting organic material. The deposition can in this case once again be effected, in principle, by any desired deposition process, for example by spin-coating, doctor blading, knife-coating, printing or combinations of the stated and/or other deposition methods.

The organic p-type semiconductor may especially comprise at least one spiro compound such as spiro-MeOTAD and/or at least one compound with the structural formula:

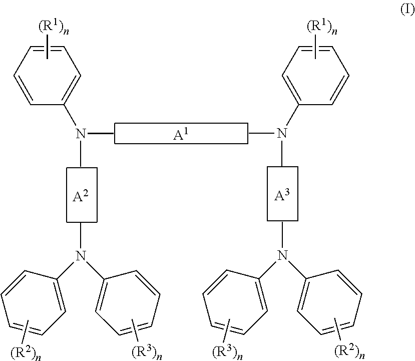

in which
A¹, A², A³ are each independently optionally substituted aryl groups or heteroaryl groups,
R¹, R², R³ are each independently selected from the group consisting of the substituents —R, —OR, —NR₂, -A⁴-OR and -A⁴-NR₂,
where R is selected from the group consisting of alkyl, aryl and heteroaryl,
and
where A⁴ is an aryl group or heteroaryl group, and
where n at each instance in formula I is independently a value of 0, 1, 2 or 3,
with the proviso that the sum of the individual n values is at least 2 and at least two of the R¹, R² and R³ radicals are —OR and/or —NR₂.

Preferably, A² and A³ are the same; accordingly, the compound of the formula (I) preferably has the following structure (Ia)

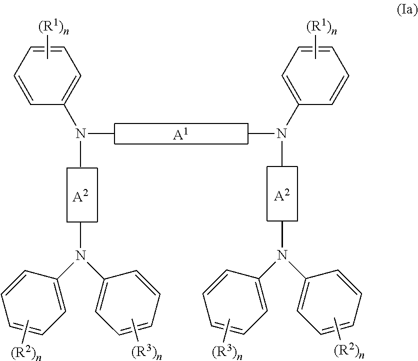

Additionally or alternatively, one or more organic p-type semiconductors as disclosed in JPH08292586 A may be used.

More particularly, as explained above, the p-type semiconductor may thus have at least one low molecular weight organic p-type semiconductor. A low molecular weight material is generally understood to mean a material which is present in monomeric, nonpolymerized or nonoligomerized form. The term “low molecular weight” as used in the present context preferably means that the p-type semiconductor has molecular weights in the range from 100 to 25 000 g/mol. Preferably, the low molecular weight substances have molecular weights of 500 to 2000 g/mol.

In general, in the context of the present invention, p-semiconducting properties are understood to mean the property of materials, especially of organic molecules, to form holes and to transport these holes and/or to pass them on to adjacent molecules. More particularly, stable oxidation of these molecules should be possible. In addition, the low molecular weight organic p-type semiconductors mentioned may especially have an extensive π-electron system. More particularly, the at least one low molecular weight p-type semiconductor may be processable from a solution. The low molecular weight p-type semiconductor may especially comprise at least one triphenylamine. It is particularly preferred when the low molecular weight organic p-type semiconductor comprises at least one spiro compound. A spiro compound is understood to mean polycyclic organic compounds whose rings are joined only at one atom, which is also referred to as the spiro atom. More particularly, the spiro atom may be sp³-hybridized, such that the constituents of the spiro compound connected to one another via the spiro atom are, for example, arranged in different planes with respect to one another.

More preferably, the spiro compound has a structure of the following formula:

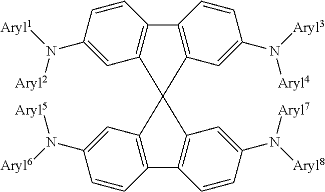

where the aryl¹, aryl², aryl³, aryl⁴, aryl⁵, aryl⁶, aryl⁷ and aryl⁸ radicals are each independently selected from substituted aryl radicals and heteroaryl radicals, especially from substituted phenyl radicals, where the aryl radicals and heteroaryl radicals, preferably the phenyl radicals, are each independently substituted, preferably in each case by one or more substituents selected from the group consisting of —O-alkyl, —OH, —F, —Cl, —Br and —I, where alkyl is preferably methyl, ethyl, propyl or isopropyl. More preferably, the phenyl radicals are each independently substituted, in each case by one or more substituents selected from the group consisting of —O-Me, —OH, —F, —Cl, —Br and —I.

Further preferably, the spiro compound is a compound of the following formula:

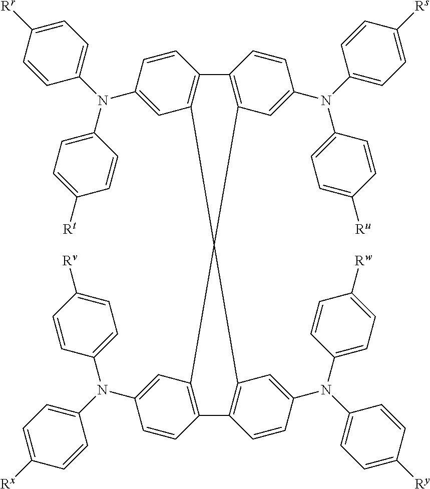

where R^{r}, R^{s}, R^{t}, R^{u}, R^{v}, R^{w}, R^{x} and R^{y} are each independently selected from the group consisting of —O-alkyl, —OH, —F, —Cl, —Br and —I, where alkyl is preferably methyl, ethyl, propyl or isopropyl. More preferably, R^{r}, R^{s}, R^{t}, R^{u}, R^{v}, R^{w}, R^{x} and R^{y} are each independently selected from the group consisting of —O-Me, —OH, —F, —Cl, —Br and —I. More particularly, the p-type semiconductor may comprise spiro-MeOTAD or consist of spiro-MeOTAD, i.e. a compound of the formula below, commercially available from Merck KGaA, Darmstadt, Germany:

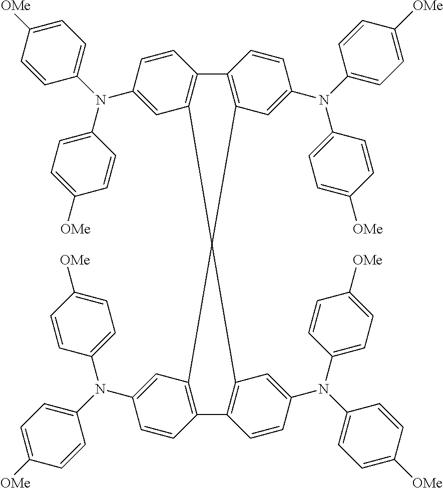 [SMILES: COc1ccc(N(c2ccc(OC)cc2)c2ccc3c(c2)C2(c4cc(N(c5ccc(OC)cc5)c5ccc(OC)cc5)ccc4-3)c3cc(N(c4ccc(OC)cc4)c4ccc(OC)cc4)ccc3-c3ccc(N(c4ccc(OC)cc4)c4ccc(OC)cc4)cc32)cc1]

Alternatively or additionally, it is also possible to use other p-semiconducting compounds, especially low molecular weight and/or oligomeric and/or polymeric p-semiconducting compounds.

In an alternative embodiment, the low molecular weight organic p-type semiconductor comprises one or more compounds of the above-mentioned general formula I, for which reference may be made, for example, to PCT application number PCT/EP2010/051826. The p-type semiconductor may comprise the at least one compound of the above-mentioned general formula I additionally or alternatively to the spiro compound described above.

The term “alkyl” or “alkyl group” or “alkyl radical” as used in the context of the present invention is understood to mean substituted or unsubstituted C₁-C₂₀-alkyl radicals in general. Preference is given to C₁- to C₁₀-alkyl radicals, particular preference to C₁- to C₈-alkyl radicals. The alkyl radicals may be either straight-chain or branched. In addition, the alkyl radicals may be substituted by one or more substituents selected from the group consisting of C₁-C₂₀-alkoxy, halogen, preferably F, and C₆-C₃₀-aryl which may in turn be substituted or unsubstituted. Examples of suitable alkyl groups are methyl, ethyl, propyl, butyl, pentyl, hexyl, heptyl and octyl, and also isopropyl, isobutyl, isopentyl, sec-butyl, tert-butyl, neopentyl, 3,3-dimethylbutyl, 2-ethylhexyl, and also derivatives of the alkyl groups mentioned substituted by C₆-C₃₀-aryl, C₁-C₂₀-alkoxy and/or halogen, especially F, for example CF₃.

The term “aryl” or “aryl group” or “aryl radical” as used in the context of the present invention is understood to mean optionally substituted C₆-C₃₀-aryl radicals which are derived from monocyclic, bicyclic, tricyclic or else multicyclic aromatic rings, where the aromatic rings do not comprise any ring heteroatoms. The aryl radical preferably comprises 5- and/or 6-membered aromatic rings. When the aryls are not monocyclic systems, in the case of the term “aryl” for the second ring, the saturated form (perhydro form) or the partly unsaturated form (for example the dihydro form or tetrahydro form), provided the particular forms are known and stable, is also possible. The term “aryl” in the context of the present invention thus comprises, for example, also bicyclic or tricyclic radicals in which either both or all three radicals are aromatic, and also bicyclic or tricyclic radicals in which only one ring is aromatic, and also tricyclic radicals in which two rings are aromatic. Examples of aryl are: phenyl, naphthyl, indanyl, 1,2-dihydronaphthenyl, 1,4-dihydronaphthenyl, fluorenyl, indenyl, anthracenyl, phenanthrenyl or 1,2,3,4-tetrahydronaphthyl. Particular preference is given to C₆-C₁₀-aryl radicals, for example phenyl or naphthyl, very particular preference to C₆-aryl radicals, for example phenyl. In addition, the term “aryl” also comprises ring systems comprising at least two monocyclic, bicyclic or multicyclic aromatic rings joined to one another via single or double bonds. One example is that of biphenyl groups.

The term “heteroaryl” or “heteroaryl group” or “heteroaryl radical” as used in the context of the present invention is understood to mean optionally substituted 5- or 6-membered aromatic rings and multicyclic rings, for example bicyclic and tricyclic compounds having at least one heteroatom in at least one ring. The heteroaryls in the context of the invention preferably comprise 5 to 30 ring atoms. They may be monocyclic, bicyclic or tricyclic, and some can be derived from the aforementioned aryl by replacing at least one carbon atom in the aryl base skeleton with a heteroatom. Preferred heteroatoms are N, O and S. The hetaryl radicals more preferably have 5 to 13 ring atoms. The base skeleton of the heteroaryl radicals is especially preferably selected from systems such as pyridine and five-membered heteroaromatics such as thiophene, pyrrole, imidazole or furan. These base skeletons may optionally be fused to one or two six-membered aromatic radicals. In addition, the term “heteroaryl” also comprises ring systems comprising at least two monocyclic, bicyclic or multicyclic aromatic rings joined to one another via single or double bonds, where at least one ring comprises a heteroatom. When the heteroaryls are not monocyclic systems, in the case of the term “heteroaryl” for at least one ring, the saturated form (perhydro form) or the partly unsaturated form (for example the dihydro form or tetrahydro form), provided the particular forms are known and stable, is also possible. The term “heteroaryl” in the context of the present invention thus comprises, for example, also bicyclic or tricyclic radicals in which either both or all three radicals are aromatic, and also bicyclic or tricyclic radicals in which only one ring is aromatic, and also tricyclic radicals in which two rings are aromatic, where at least one of the rings, i.e. at least one aromatic or one nonaromatic ring has a heteroatom. Suitable fused heteroaromatics are, for example, carbazolyl, benzimidazolyl, benzofuryl, dibenzofuryl or dibenzothiophenyl. The base skeleton may be substituted at one, more than one or all substitutable positions, suitable substituents being the same as have already been specified under the definition of C₆-C₃₀-aryl. However, the hetaryl radicals are preferably unsubstituted. Suitable hetaryl radicals are, for example, pyridin-2-yl, pyridin-3-yl, pyridin-4-yl, thiophen-2-yl, thiophen-3-yl, pyrrol-2-yl, pyrrol-3-yl, furan-2-yl, furan-3-yl and imidazol-2-yl and the corresponding benzofused radicals, especially carbazolyl, benzimidazolyl, benzofuryl, dibenzofuryl or dibenzothiophenyl.

In the context of the invention, the term “optionally substituted” refers to radicals in which at least one hydrogen radical of an alkyl group, aryl group or heteroaryl group has been replaced by a substituent. With regard to the type of this substituent, preference is given to alkyl radicals, for example methyl, ethyl, propyl, butyl, pentyl, hexyl, heptyl and octyl, and also isopropyl, isobutyl, isopentyl, sec-butyl, tert-butyl, neopentyl, 3,3-dimethylbutyl and 2-ethylhexyl, aryl radicals, for example C₆-C₁₀-aryl radicals, especially phenyl or naphthyl, most preferably C₆-aryl radicals, for example phenyl, and hetaryl radicals, for example pyridin-2-yl, pyridin-3-yl, pyridin-4-yl, thiophen-2-yl, thiophen-3-yl, pyrrol-2-yl, pyrrol-3-yl, furan-2-yl, furan-3-yl and imidazol-2-yl, and also the corresponding benzofused radicals, especially carbazolyl, benzimidazolyl, benzofuryl, dibenzofuryl or dibenzothiophenyl. Further examples include the following substituents: alkenyl, alkynyl, halogen, hydroxyl.

The degree of substitution here may vary from monosubstitution up to the maximum number of possible substituents.

Preferred compounds of the formula I for use in accordance with the invention are notable in that at least two of the R¹, R² and R³ radicals are para-OR and/or —NR₂ substituents. The at least two radicals here may be only —OR radicals, only —NR₂ radicals, or at least one —OR and at least one —NR₂ radical.

Particularly preferred compounds of the formula I for use in accordance with the invention are notable in that at least four of the R¹, R² and R³ radicals are para-OR and/or —NR₂ substituents.

The at least four radicals here may be only —OR radicals, only —NR₂ radicals or a mixture of —OR and —NR₂ radicals.

Very particularly preferred compounds of the formula I for use in accordance with the invention are notable in that all of the R¹, R² and R³ radicals are para-OR and/or —NR₂ substituents. They may be only —OR radicals, only —NR₂ radicals or a mixture of —OR and —NR₂ radicals.

In all cases, the two R in the —NR₂ radicals may be different from one another, but they are preferably the same.

Preferably, A¹, A² and A³ are each independently selected from the group consisting of

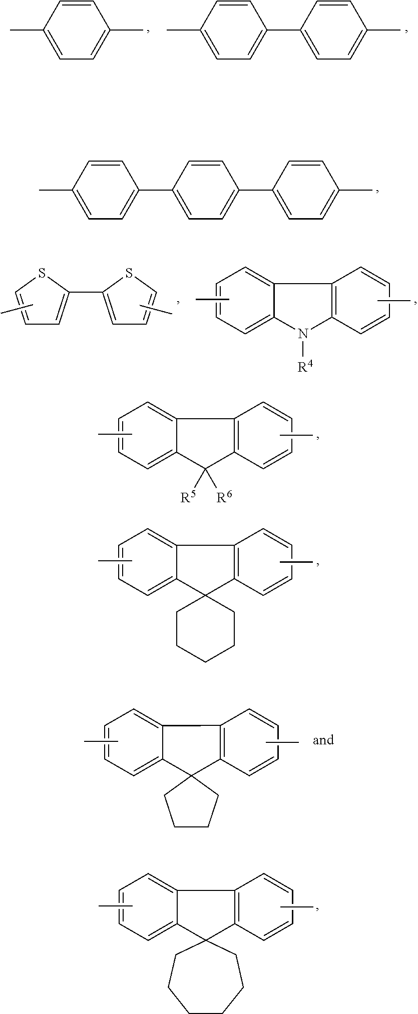

in which
m is an integer from 1 to 18,
R⁴ is alkyl, aryl or heteroaryl, where R⁴ is preferably an aryl radical, more preferably a phenyl radical,
R⁵, R⁶ are each independently H, alkyl, aryl or heteroaryl,
where the aromatic and heteroaromatic rings of the structures shown may optionally have further substitution. The degree of substitution of the aromatic and heteroaromatic rings here may vary from monosubstitution up to the maximum number of possible substituents.

Preferred substituents in the case of further substitution of the aromatic and heteroaromatic rings include the substituents already mentioned above for the one, two or three optionally substituted aromatic or heteroaromatic groups.

Preferably, the aromatic and heteroaromatic rings of the structures shown do not have further substitution.

More preferably, A¹, A² and A³ are each independently

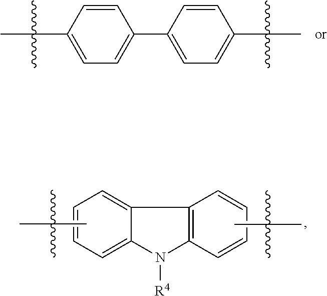

more preferably

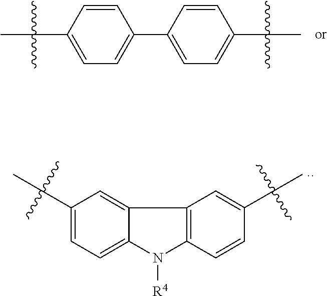

More preferably, the at least one compound of the formula (I) has one of the following structures

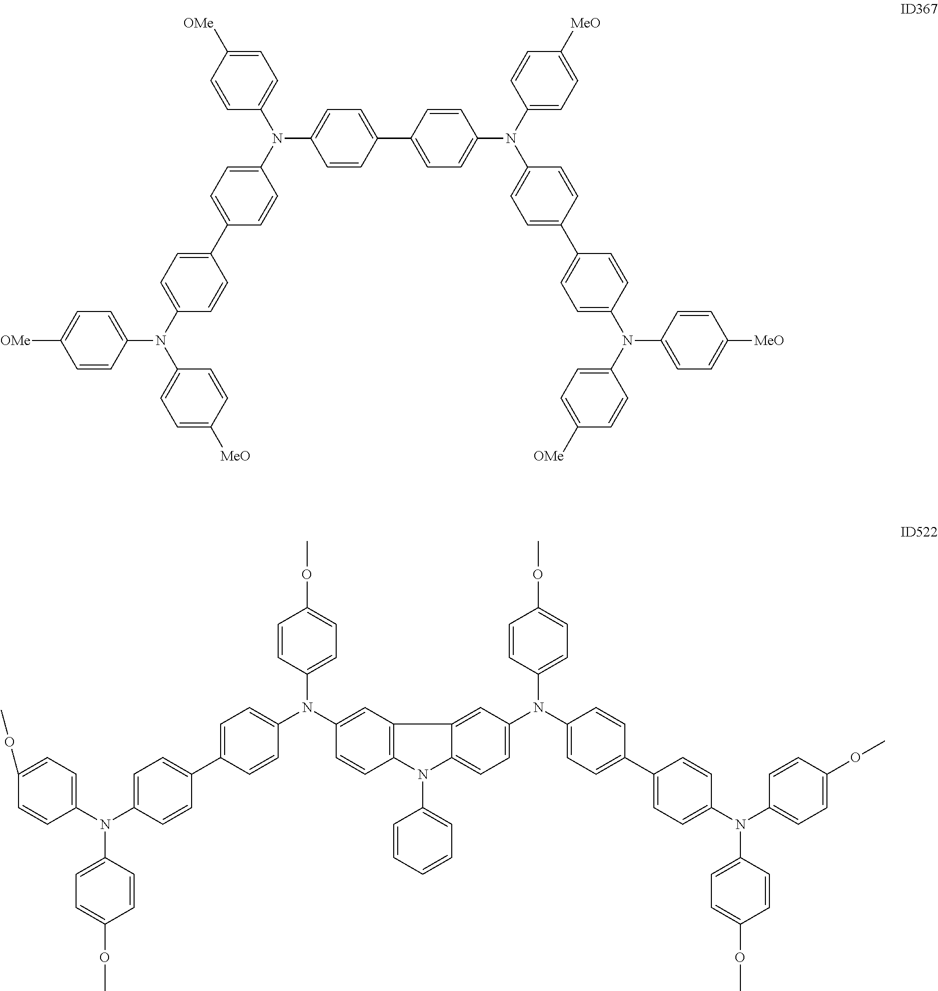

In an alternative embodiment, the organic p-type semiconductor comprises a compound of the type ID322 having the following structure:

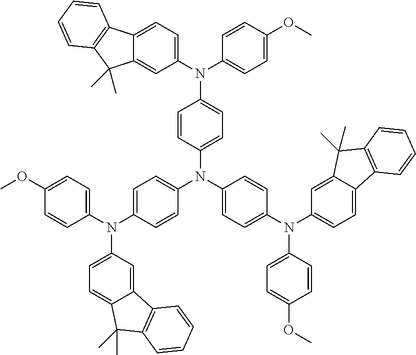 [SMILES: COc1ccc(N(c2ccc(N(c3ccc(N(c4ccc(OC)cc4)c4ccc5c(c4)C(C)(C)c4ccccc4-5)cc3)c3ccc(N(c4ccc(OC)cc4)c4ccc5c(c4)C(C)(C)c4ccccc4-5)cc3)cc2)c2ccc3c(c2)-c2ccccc2C3(C)C)cc1]

The compounds for use in accordance with the invention can be prepared by customary methods of organic synthesis known to those skilled in the art. References to relevant (patent) literature can additionally be found in the synthesis examples adduced below.

### d) Second Electrode

The second electrode may be a bottom electrode facing the substrate or else a top electrode facing away from the substrate. As outlined above, the second electrode may be fully or partially transparent or, else, may be intransparent. As used herein, the term partially transparent refers to the fact that the second electrode may comprise transparent regions and intransparent regions.

One or more materials of the following group of materials may be used: at least one metallic material, preferably a metallic material selected from the group consisting of aluminum, silver, platinum, gold; at least one nonmetallic inorganic material, preferably LiF; at least one organic conductive material, preferably at least one electrically conductive polymer and, more preferably, at least one transparent electrically conductive polymer.

The second electrode may comprise at least one metal electrode, wherein one or more metals in pure form or as a mixture/alloy, such as especially aluminum or silver may be used.

Additionally or alternatively, nonmetallic materials may be used, such as inorganic materials and/or organic materials, both alone and in combination with metal electrodes. As an example, the use of inorganic/organic mixed electrodes or multilayer electrodes is possible, for example the use of LiF/Al electrodes. Additionally or alternatively, conductive polymers may be used. Thus, the second electrode of the optical sensor preferably may comprise one or more conductive polymers.

Thus, as an example, the second electrode may comprise one or more electrically conductive polymers, in combination with one or more layers of a metal. Preferably, the at least one electrically conductive polymer is a transparent electrically conductive polymer. This combination allows for providing very thin and, thus, transparent metal layers, by still providing sufficient electrical conductivity in order to render the second electrode both transparent and highly electrically conductive. Thus, as an example, the one or more metal layers, each or in combination, may have a thickness of less than 50 nm, preferably less than 40 nm or even less than 30 nm.

As an example, one or more electrically conductive polymers may be used, selected from the group consisting of: polyanaline (PANI) and/or its chemical relatives; a polythiophene and/or its chemical relatives, such as poly(3-hexylthiophene) (P3HT) and/or PEDOT:PSS (poly(3,4-ethylenedioxythiophene) poly(styrenesulfonate)). Additionally or alternatively, one or more of the conductive polymers as disclosed in EP2507286 A2, EP2205657 A1 or EP2220141 A1. For further exemplary embodiments, reference may be made to U.S. provisional application No. 61/739,173 or U.S. provisional application No. 61/708,058, the full content of all of which is herewith included by reference.

In addition or alternatively, inorganic conductive materials may be used, such as inorganic conductive carbon materials, such as carbon materials selected from the group consisting of: graphite, graphene, carbon nano-tubes, carbon nano-wires.

In addition, it is also possible to use electrode designs in which the quantum efficiency of the components is increased by virtue of the photons being forced, by means of appropriate reflections, to pass through the absorbing layers at least twice. Such layer structures are also referred to as “concentrators” and are likewise described, for example, in WO 02/101838 (especially pages 23-24).

In the following, some exemplary embodiments of the optional sensor stack comprising two or more optical sensors and of potential evaluation techniques are explained.

As an example, the evaluation device may be or may comprise one or more integrated circuits, such as one or more application-specific integrated circuits (ASICs), and/or one or more data processing devices, such as one or more computers, preferably one or more microcomputers and/or microcontrollers. Additional components may be comprised, such as one or more preprocessing devices and/or data acquisition devices, such as one or more devices for receiving and/or preprocessing of the sensor signal, such as one or more AD-converters and/or one or more filters. Further, the evaluation device may comprise one or more data storage devices. Further, the evaluation device may comprise one or more interfaces, such as one or more wireless interfaces and/or one or more wire-bound interfaces.

As outlined above, the at least one sensor signal, given the same total power of the illumination by the light beam, is dependent on a beam cross-section of the light beam in the sensor region of the at least one optical sensor. As used herein, the term beam cross-section generally refers to a lateral extension of the light beam or a light spot generated by the light beam at a specific location. In case a circular light spot is generated, a radius, a diameter or a Gaussian beam waist or twice the Gaussian beam waist may function as a measure of the beam cross-section. In case non-circular light spots are generated, the cross-section may be determined in any other feasible way, such as by determining the cross-section of a circle having the same area as the non-circular light spot, which is also referred to as the equivalent beam cross-section.

Thus, given the same total power of the illumination of the sensor region by the light beam, a light beam having a first beam diameter or beam cross-section may generate a first sensor signal, whereas a light beam having a second beam diameter or beam-cross section being different from the first beam diameter or beam cross-section generates a second sensor signal being different from the first sensor signal. Thus, by comparing the sensor signals, an item of information or at least one item of information on the beam cross-section, specifically on the beam diameter, may be generated. For details of this effect, reference may be made to one or more of WO 2012/110924 A1, U.S. provisional applications No. 61/739,173, No. 61/749,964, or No. 61/867,169, or international patent application PCT/IB2013/061095. Specifically in case one or more beam properties of the light beam are known, specifically before interacting with the at least one safety mark, such as by providing a well-defined light beam and/or by using a well-defined optical system and/or by measuring beam properties, the modifications introduced into the light beam by the interaction of the light beam with the safety mark may thus be derived from a known relationship between the at least one sensor signal and corresponding properties of the safety mark. Thereby, as an example, a focusing or a defocusing such as by a lens effect of the safety mark may be determined. As an example, a focal length of one or more lenses contained within the safety mark, such as one or more Fresnel lenses, may form at least one characteristic parameter of the safety mark which may be determined by a FiP measurement and which may be used for verification and/or identification purposes. The known relationship may be stored in the evaluation device as an algorithm and/or as one or more calibration curves. As an example, specifically for Gaussian beams, a relationship between a beam diameter or beam waist and the respective depth may easily be derived by using the Gaussian relationship between the beam waist and the focal length of the lens contained within the safety Mark.

The above-mentioned effect, which is also referred to as the FiP-effect (alluding to the effect that the beam cross section φ influences the electric power P generated by the optical sensor), may depend on or may be emphasized by an appropriate modulation of the light beam, as disclosed in one or more of WO 2012/110924 A1, U.S. provisional applications No. 61/739,173, No. 61/749,964, or No. 61/867,169, or international patent application PCT/IB2013/061095. Thus, optionally, the detector may furthermore have at least one modulation device for modulating the at least one light beam. The modulation device may fully or partially be implemented into the at least one illumination source and/or may fully or partially be designed as a separate modulation device. By way of example, the verification device and/or the detector can be designed to bring about a modulation of the light beam with a frequency of 0.05 Hz to 1 MHz, such as 0.1 Hz to 10 kHz, specifically for the purpose of the FiP effect.

The modulation of the light beam may take place in different frequency ranges and/or may be established in various ways. Thus, the detector can furthermore have at least one modulation device. Generally, a modulation of a light beam should be understood to mean a process in which a total power and/or a phase, most preferably a total power, of the respective light beam is varied, preferably periodically, in particular with one or a plurality of modulation frequencies. In particular, a periodic modulation can be effected between a maximum value and a minimum value of the total power of the illumination. The minimum value can be 0, but can also be >0, such that, by way of example, complete modulation does not have to be effected. The modulation can be effected for example in a beam path between the illumination source and the safety mark and/or in between the safety mark and the at least one optical sensor. Alternatively or additionally, the modulation may also be performed by the illumination source itself. The at least one modulation device can comprise for example a beam chopper or some other type of periodic beam interrupting device, for example comprising at least one interrupter blade or interrupter wheel, which preferably rotates at constant speed and which can thus periodically interrupt the illumination. Alternatively or additionally, however, it is also possible to use one or a plurality of different types of modulation devices, for example modulation devices based on an electro-optical effect and/or an acousto-optical effect. Once again alternatively or additionally, the at least one optional illumination source itself can also be designed to generate a modulated illumination, for example by said illumination source itself having a modulated intensity and/or total power, for example a periodically modulated total power, and/or by said illumination source being embodied as a pulsed illumination source, for example as a pulsed laser. Thus, by way of example, the at least one modulation device can also be wholly or partly integrated into the illumination source.

The detector may be designed to detect at least two sensor signals in the case of different modulations, in particular at least two sensor signals at respectively different modulation frequencies. In this case, the evaluation device may be designed to generate the at least one item of information on identity of the article by evaluating the at least two sensor signals.

Generally, the optical sensor may be designed in such a way that the at least one sensor signal, given the same total power of the illumination, is dependent on a modulation frequency of a modulation of the illumination by the light beam. Further details and exemplary embodiments will be given below. This property of frequency dependency is specifically provided in DSCs and, more preferably, in sDSCs. However, other types of optical sensors, preferably photo detectors and, more preferably, organic photo detectors may exhibit this effect.

Preferably, the at least one optical sensor is a thin film device, having a layer setup with a thickness of preferably no more than 1 mm, more preferably of at most 500 μm or even less. Thus, the sensor region of the optical sensor may be or may comprise a sensor area, which may be formed by a surface of the respective device facing towards the object.

Preferably, the sensor region of the optical sensor may be formed by one continuous sensor region, such as one continuous sensor area or sensor surface per device. Thus, preferably, the sensor region of the optical sensor or, in case a plurality of optical sensors is provided (such as a stack of optical sensors), each sensor region of the optical sensor, may be formed by exactly one continuous sensor region. The sensor signal preferably is a uniform sensor signal for the entire sensor region of the optical sensor or, in case a plurality of optical sensors is provided, is a uniform sensor signal for each sensor region of each optical sensor.

As outlined above, the detector preferably has a plurality of the optical sensors. More preferably, the plurality of optical sensors is stacked, such as along the optical axis of the detector. Thus, the optical sensors may form an optical sensor stack. The optical sensor stack preferably may be oriented such that the sensor regions of the optical sensors are oriented perpendicular to the optical axis. Thus, as an example, sensor areas or sensor surfaces of the single optical sensors may be oriented in parallel, wherein slight angular tolerances might be tolerable, such as angular tolerances of no more than 10°, preferably of no more than 5°.

The optical sensors preferably are arranged such that the light beam illuminates all optical sensors, preferably sequentially. Specifically in this case, preferably, at least one sensor signal is generated by each optical sensor. This embodiment is specifically preferred since the stacked setup of the optical sensors allows for an easy and efficient normalization of the sensor signals, even if an overall power or intensity of the light beam is unknown. Thus, the single sensor signals may be known to be generated by one and the same light beam. Thus, the evaluation device may be adapted to normalize the sensor signals. The evaluation device may further be adapted to generate at least one item of information regarding the identity of the article independent from an intensity of the light beam. For this purpose, use may be made of the fact that, in case the single sensor signals are generated by one and the same light beam, differences in the single sensor signals are only due to differences in the cross-sections of the light beam at the location of the respective sensor regions of the single optical sensors. Thus, by comparing the single sensor signals, information on a beam cross-section may be generated even if the overall power of the light beam is unknown. From the beam cross-section, information regarding the depth may be gained, specifically by making use of a known relationship between the cross-section of the light beam and the depth.

Further, the above-mentioned stacking of the optical sensors and the generation of a plurality of sensor signals by these stacked optical sensors may be used by the evaluation device in order to resolve an ambiguity in a known relationship between a beam cross-section of the light beam and the depth.

The devices and methods according to the present invention provide a large number of advantages over known devices and methods. Thus, the above-mentioned FiP effect as known from the above-mentioned prior art documents may be used in combination with at least one safety mark, in a verification device. The verification device may be used in shops, ATMs, vending machines, etc. An active FiP-measurement, as may be performed with the present verification device and verification system, may involve (1) an illumination source such as a lamp illuminating the article; (2) an article, such as an object, having one or more safety marks reflecting and/or transmitting the light beam generated by the illumination source; (3) optionally one or more transfer devices such as one or more lenses focusing the light beam onto the safety mark and/or focusing the light beam onto at least one optical sensor of a detector; (4) at least one detector having at least one optical sensor exhibiting the above-mentioned FiP-effect. Items (1), (3) and (4) may be part of a verification device which, again, with item (2) may form a part of a verification system. A safety mark verification measurement, such as for verifying a bill and/or a credit card, may involve (a) illuminating the article to be verified with at least one light beam; (b) an interaction of the light beam with at least one safety mark attached to and/or integrated into the article, wherein the at least one light beam is fully or partially reflected and/or transmitted; (c) detecting and evaluating the light beam by using at least one detector having at least one optical sensor exhibiting the above-mentioned FiP-effect, and by using at least one evaluation device. The illumination source, such as a lamp, may emit light of a well-defined wavelength or wavelength regime, which could further be modified by a color filter. Thus, the verification device in general and, more specifically, the illumination source, may comprise one or more wavelength selective elements, such as one or more color filters.

The safety mark, as outlined above, may be or may contain one or more of a fully or partially reflecting safety mark or a fully or partially transmitting safety mark. The safety mark in general may be adapted for modifying the light beam upon transmission and/or reflection. Examples of modifications are: a change of polarization, a change of wavelength, a focusing or defocussing of the light beam (such as by a lens, a Fresnel lens, etc.), or modifying the direction of the light beam. The safety mark may also introduce a 2d structure such as an xy-structure into the light beam, such as by changing one or more of color, polarity, focus, etc. in an object plane. If the article permits, the transmission or reflection may also cause the light to have several focal points on the at least one optical sensor, i.e. the at least one FiP-sensor, such as by providing a plurality of fully or partially reflecting surfaces, or lenses with several different focal points. The safety mark itself may be embodied such that a reproduction of the safety mark is difficult, specifically for potential infringers and/or counterfeiters.

The detector of the at least one verification device may contain at least one FiP-sensor which may be produced as such that a well-defined FiP-signal must be measured to confirm safety. Thus, generally, based on the at least one sensor signal of the at least one optical sensor, the evaluation device may perform at least one verification step. The at least one optical sensor, i.e. the at least one FiP-sensor, may also contain one or more dyes of limited availability. Further, the detector may contain a plurality of optical sensors having differing spectral sensitivities, wherein the evaluation device may be adapted to compare sensor signals of the optical sensors having differing spectral sensitivities in order to generate at least one item of color information, such as for evaluating a color of the light beam after interaction with the at least one safety mark. Thus, a color change of the light beam after interaction with the at least one safety mark may be evaluated and may be used as an additional item of information usable for the verification of the article. As outlined above, the FiP-effect can also be used in combination with other identification effects or techniques, such as in combination with at least one RFID-tag, wherein the at least one safety mark and the at least one identifier such as the at least one RFID-tag may be one or both of attached to the article or integrated into the optical, such as in a combined identifier and/or as separate identifiers.

Overall, in the context of the present invention, the following embodiments are regarded as preferred:

### Embodiment 1

A verification device for verifying the identity of an article, the verification device comprising:
at least one illumination source for illuminating at least one safety mark of the article with at least one light beam;
at least one detector adapted for detecting after an interaction of the light beam with the safety mark, the detector having at least one optical sensor, wherein the optical sensor has at least one sensor region, wherein the optical sensor is designed to generate at least one sensor signal in a manner dependent on an illumination of the sensor region by the light beam, wherein the sensor signal, given the same total power of the illumination, is dependent on a beam cross-section of the light beam in the sensor region; and
at least one evaluation device adapted for evaluating the sensor signal and for verifying the identity of the article on the basis of the sensor signal.

### Embodiment 2

The verification device according to the preceding embodiment, wherein the evaluation device is adapted to determine at least one modification of at least one property of the light beam by evaluating the sensor signal, the modification being induced by the interaction of the light beam with the safety mark.

### Embodiment 3

The verification device according to the preceding embodiment, wherein the evaluation device is adapted to compare the modification of the at least one property of the light beam with at least one predetermined modification.

### Embodiment 4

The verification device according to the preceding embodiment, wherein the evaluation device is adapted to verify the identity of the article in case the modification corresponds to the predetermined modification and to deny a verification of the identity of the optical in case the modification fails to correspond to the predetermined modification.

### Embodiment 5

The verification device according to any one of the two preceding embodiments, wherein the evaluation device is adapted to retrieve the at least one predetermined modification from at least one of a data storage device or a data transfer via at least one electronic interface.

### Embodiment 6

The verification device according to any one of the four preceding embodiments, wherein the at least one property of the light beam modified by the interaction with the safety mark is selected from the group consisting of: a beam parameter of the light beam, preferably a beam parameter selected from the group consisting of a beam waist, a Rayleigh length, a focal position, a beam waist at a focal position, a Gaussian beam parameter; a polarization of the light beam; a spectral property of the light beam, preferably a color of the light beam and/or a wavelength of the light beam; a focusing or a defocusing of the light beam; a direction of propagation of the light beam.

### Embodiment 7

The verification device according to any one of the preceding embodiments, wherein the evaluation device is adapted to determine a beam cross-section of the light beam in the sensor region by evaluating the sensor signal and by taking into account known beam properties of the light beam.

### Embodiment 8

The verification device according to the preceding embodiment, wherein the evaluation device is adapted to determine a change of the beam cross-section of the light beam induced by the interaction with the safety mark.

### Embodiment 9

The verification device according to any one of the preceding embodiments, wherein the verification device further comprises at least one modulation device for modulating at least one property of the light beam, preferably for periodically modulating an intensity of light beam.

### Embodiment 10

The verification device according to any one of the preceding embodiments, wherein the optical sensor is an organic photodetector, preferably an organic solar cell, more preferably a dye-sensitized organic solar cell and most preferably a solid dye-sensitized organic solar cell.

### Embodiment 11

The verification device according to any one of the preceding embodiments, wherein the optical sensor comprises at least one photosensitive layer setup, the photosensitive layer setup having at least one first electrode, at least one second electrode and at least one photovoltaic material sandwiched in between the first electrode and the second electrode, wherein the photovoltaic material comprises at least one organic material.

### Embodiment 12

The verification device according to the preceding embodiment, wherein the photosensitive layer setup comprises an n-semiconducting metal oxide, preferably a nano-porous n-semiconducting metal oxide, wherein the photosensitive layer setup further comprises at least one solid p-semiconducting organic material deposited on top of the n-semiconducting metal oxide.

### Embodiment 13

The verification device according to the preceding embodiment, wherein the n-semiconducting metal oxide is sensitized by using at least one dye.

### Embodiment 14

The verification device according to any one of the three preceding embodiments, wherein at least one of the first electrode or the second electrode are fully or partially transparent.

### Embodiment 15

The verification device according to any one of the preceding embodiments, wherein the detector further comprises at least one transfer device adapted for transferring the light beam to the at least one optical sensor.

### Embodiment 16

The verification device according to the preceding embodiment, wherein the transfer device comprises at least one lens or lens system.

### Embodiment 17

The verification device according to any one of the preceding embodiments, wherein the detector comprises a stack of at least two optical sensors.

### Embodiment 18

The verification device according to the preceding embodiment, wherein at least one optical sensor of the stack is at least partially transparent.

### Embodiment 19

The verification device according to any one of the two preceding embodiments, wherein the evaluation device is adapted to evaluate at least the sensor signals generated by at least two of the optical sensors of the stack.

### Embodiment 20

The verification device according to the preceding embodiment, wherein the evaluation device is adapted to derive at least one beam parameter from the at least two sensor signals generated by the at least two optical sensors of the stack.

### Embodiment 21

The verification device according to any one of the preceding embodiments, wherein the illumination source comprises at least one laser.

### Embodiment 22

The verification device according to any one of the preceding embodiments, wherein the illumination source is adapted to generate at least two different light beams having different colors.

### Embodiment 23

The verification device according to the preceding embodiment, wherein the detector is adapted for distinguishing between light beams having different colors.

### Embodiment 24

The verification device according to the preceding embodiment, wherein the detector comprises at least two optical sensors having differing spectral sensitivities.

### Embodiment 25

The verification device according to any one of the preceding embodiments, wherein the verification device comprises at least one of: a cashbox; a vending machine; an ATM.

### Embodiment 26

A verification system for verifying the identity of an article, the verification system comprising at least one verification device according to any one of the preceding embodiments, the verification system further comprising at least one article, the at least one article having at least one safety mark, the safety mark being adapted for interacting with the at least one light beam, the safety mark being adapted for modifying at least one property of the light beam when interacting with the light beam.

### Embodiment 27

The verification system according to the preceding embodiment, wherein the safety mark comprises at least one element selected from the group consisting of: an element adapted for modifying at least one beam parameter of the light beam, preferably a beam parameter selected from the group consisting of a beam waist, a Rayleigh length, a focal position, a beam waist at a focal position, a Gaussian beam parameter; a lens or lens system, preferably a Fresnel lens; a polarizer; a grating; an element for changing at least one spectral property of the light beam, preferably at least one element selected from the group consisting of a color filter and a wavelength-selective reflective element; an element for changing a direction of propagation of the light beam, preferably a reflective element.

### Embodiment 28

The verification system according to any one of the preceding embodiments referring to a verification system, wherein the safety mark is one of a reflective safety mark and a transmissive safety mark.

### Embodiment 29

The verification system according to any one of the preceding embodiments referring to a verification system, wherein the illumination source comprises at least one transfer device adapted for focusing the light beam onto the safety mark.

### Embodiment 30

The verification system according to any one of the preceding embodiments referring to a verification system, wherein the safety mark is adapted for generating a two-dimensional structure within the light beam, wherein the detector is adapted to at least partially determine the two-dimensional structure.

### Embodiment 31

The verification system according to any one of the preceding embodiments referring to a verification system, wherein the safety mark is adapted to subdivide the light beam into at least two partial light beams.

### Embodiment 32

The verification system according to the preceding embodiment, wherein the partial light beams have differing beam propagation properties, preferably different focal points.

### Embodiment 33

The verification system according to any one of the two preceding embodiments, wherein the safety mark comprises at least two lenses having different focal lengths.

### Embodiment 34

The verification system according to any one of the preceding embodiments referring to a verification system, wherein the article further comprises at least one additional identifier, wherein the verification device is adapted for reading out at least one verification information from the additional identifier and wherein the evaluation device is adapted to use the verification information during verifying the identity of the article.

### Embodiment 35

The verification system according to the preceding embodiment, wherein the at least one additional identifier comprises at least one of an optically readable identifier and an electronically readable identifier.

### Embodiment 36

The verification system according to any one of the two preceding embodiments, wherein the at least one additional identifier comprises at least one of the barcode and an RFID chip.

### Embodiment 37

The verification system according to any one of the preceding embodiments referring to a verification system, wherein the article is selected from the group consisting of: an article used for payment, preferably a credit card and/or a bill; an ID card; a pharmaceutical; a packaging.

### Embodiment 38

The verification system according to any one of the preceding embodiments, wherein the safety mark is adapted for modifying at least two properties of the light beam when interacting with the light beam.

### Embodiment 40

The verification system according to any one of the preceding embodiments, wherein the safety mark is adapted to be detectable by direct optical inspection, preferably with the naked eye.

### Embodiment 41

The verification system according to the preceding embodiment, wherein the safety mark comprises at least one visible feature, preferably at least one feature visible with the naked eye, more preferably one or more of a color filter, a hologram, a reflective element, an intensity change element.

### Embodiment 42

A method for verifying the identity of an article, the method comprising the following steps:
illuminating at least one safety mark of the article with at least one light beam by using at least one illumination source;
detecting the light beam after an interaction of the light beam with the safety mark by using a detector, the detector having at least one optical sensor, wherein the optical sensor has at least one sensor region, wherein the optical sensor is designed to generate at least one sensor signal in a manner dependent on an illumination of the sensor region by the light beam, wherein the sensor signal, given the same total power of the illumination, is dependent on a beam cross-section of the light beam in the sensor region; and
evaluating the sensor signal and verifying the identity of the article on the basis of the sensor signal, by using at least one evaluation device.

### Embodiment 43

The method according to the preceding embodiment, wherein the verification device according to any one of the preceding claims referring to a verification device and/or the verification system according to any one of the preceding claims referring to a verification system are used.

### Embodiment 44

A use of an optical sensor for verifying the identity of an article, the optical sensor having at least one sensor region, wherein the optical sensor is designed to generate at least one sensor signal in a manner dependent on an illumination of the sensor region by a light beam, wherein the sensor signal, given the same total power of the illumination, is dependent on a beam cross-section of the light beam in the sensor region.

### Embodiment 45

The use according to the preceding embodiment, wherein the optical sensor is an organic photodetector, preferably an organic solar cell, more preferably a dye-sensitized organic solar cell and most preferably a solid dye-sensitized organic solar cell.

### Embodiment 46

The use according to any one of the two preceding embodiments, wherein the optical sensor comprises at least one photosensitive layer setup, the photosensitive layer setup having at least one first electrode, at least one second electrode and at least one photovoltaic material sandwiched in between the first electrode and the second electrode, wherein the photovoltaic material comprises at least one organic material.

### Embodiment 47

The use according to the preceding embodiment, wherein the photosensitive layer setup comprises an n-semiconducting metal oxide, preferably a nano-porous n-semiconducting metal oxide, wherein the photosensitive layer setup further comprises at least one solid p-semiconducting organic material deposited on top of the n-semiconducting metal oxide.

### Embodiment 48

The use according to the preceding embodiment, wherein the n-semiconducting metal oxide is sensitized by using at least one dye.

### Embodiment 49

The use according to any one of the three preceding embodiments, wherein at least one of the first electrode or the second electrode are fully or partially transparent.

### BRIEF DESCRIPTION OF THE FIGURES

Further optional details and features of the invention are evident from the description of preferred exemplary embodiments which follows in conjunction with the dependent claims. In this context, the particular features may be implemented alone or with several in combination. The invention is not restricted to the exemplary embodiments. The exemplary embodiments are shown schematically in the figures. Identical reference numerals in the individual figures refer to identical elements or elements with identical function, or elements which correspond to one another with regard to their functions.

Specifically, in the figures:

FIG. 1 shows a first exemplary embodiment of a verification device and a verification system according to the present invention;

FIG. 2 shows a second exemplary embodiment of a verification device and a verification system according to the present invention; and

FIG. 3 shows an exemplary embodiment of a shift of focal position within a detector of a verification device, due to an interaction of a light beam with a safety mark.

### EXEMPLARY EMBODIMENTS

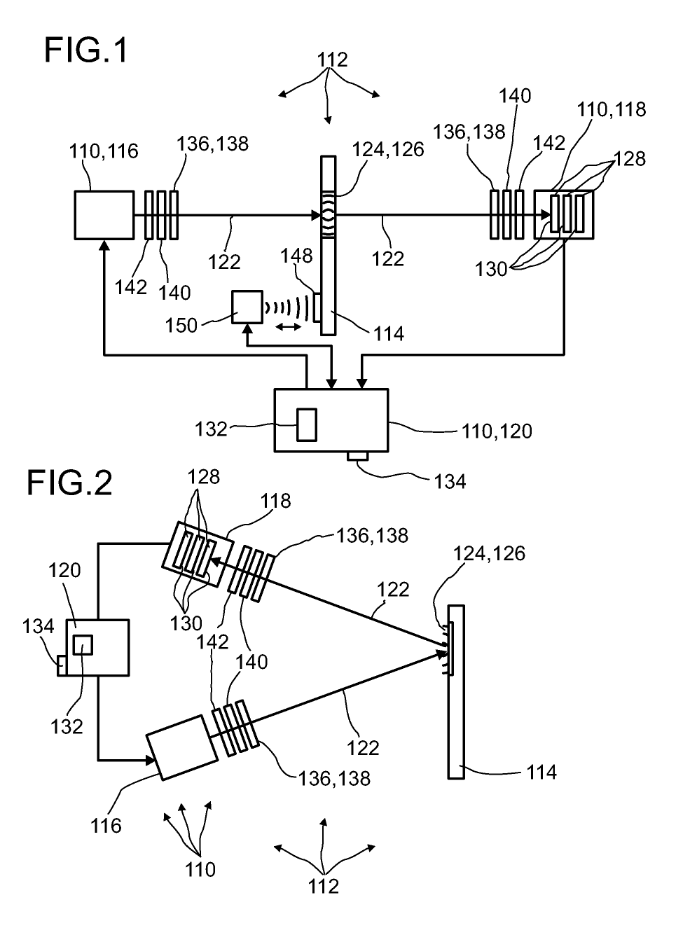

In FIG. 1, a first exemplary embodiment of a verification device 110 and a verification system 112, both adapted for verifying the identity of an article 114, is depicted. The verification device 110 comprises an illumination source 116, a detector 118 and an evaluation device 120. The verification system 112, besides the verification device 110, comprises the at least one article 114, the identity of which shall be verified.

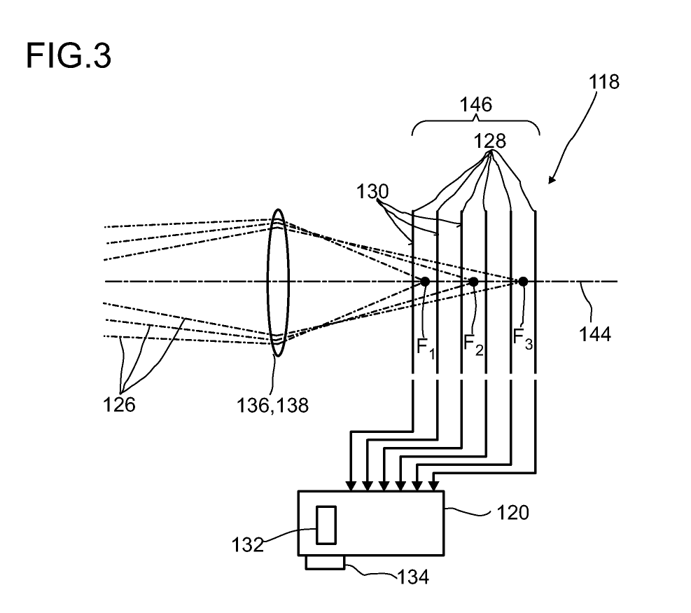

The illumination source 116, which may comprise one or more light sources such as one or more lasers or other type of light sources, is adapted to generate at least one light beam 122. The verification device 110 is adapted to direct the light beam 122 onto at least one safety mark 124 which may fully or partially be integrated into the article 114 and/or which may be attached to the article 114. In the exemplary embodiment shown in FIG. 1, the safety mark 124 is a transmissive safety mark which may allow for a transmission of the incident light beam 122. Thus, the light beam 122 is transmitted through safety mark 122 and is directed towards the detector 118. When interacting with the light beam 122, the safety mark 124 is adapted for modifying at least one property of the light beam 122 in a predetermined way, which may be unique and/or specific for the safety mark 124 and/or the article 114. Thus, by evaluating the modification of the at least one property of the light beam 122 by the safety marker 124, the identity of the safety mark 124 and, thus, the identity of the article 114 may be verified. As an example and as shown in FIG. 1, the safety mark 124 may contain one or more lenses 126, such as one or more Fresnel lenses. Thereby, as an exemplary embodiment of potential modifications of the light beam 122 by the safety mark 124, the light beam 122 may be focused and/or defocused in a characteristic way, e.g. by shifting a focal point of the light beam 122, as will be outlined in further detail below with reference to FIG. 3.

The detector 118 comprises one or more optical sensors 128, each optical sensor 128 having at least one sensor region 130. As an example, each optical sensor 128 and/or at least one of the optical sensors 128 may comprise at least one sensor region 130. The optical sensor 128 is adapted to generate at least one sensor signal in a manner dependent on an illumination of the sensor region 130 by the light beam. Given the same total power of the illumination, the sensor signal is dependent on a beam cross-section, such as on a diameter or an equivalent diameter of a light spot generated by the light beam 122 in the sensor region 130. Thus, by evaluating the sensor signal of the optical sensor 128, a beam diameter or an equivalent diameter of the light beam 122 in the sensor region 130, such as in a sensitive area of the sensor region 130, may be detected.

The detector 118 is connected to the at least one evaluation device 120. Thus, the at least one sensor signal of the at least one optical sensor 128 may directly or indirectly be transferred to the evaluation device 120. The evaluation device 120 may further fully or partially be integrated into the detector 118. The evaluation device 120 may further be connected to the least one illumination source 116, in order to control a functionality of the at least one illumination source 116. Further, the evaluation device 120 may fully or partially be integrated into the illumination source 116 or vice versa. It shall be noted that, even though components 116, 118 and 120 are depicted as individual and separate components in FIG. 1, a full or partial integration of two or more of these components is possible, such as into a common device or common casing.

The evaluation device 120 is adapted for evaluating the above-mentioned sensor signal of the at least one optical sensor 128. Thus, as outlined above, the above-mentioned optical sensor 128 is designed as a FiP-sensor, exhibiting the above-mentioned FiP-effect. For exemplary embodiments of potential setups of the at least one optical sensor 128, reference may be made to the specification given above and/or to one or more of the above-mentioned prior art documents. Specifically, reference may be made to one or more of WO 2012/110924 A1, the content of which is herewith included by reference, as well as to international patent application no. PCT/IB2013/061095, the full content of which is herewith included by reference, too. Other embodiments are feasible.

The evaluation device is adapted for evaluating the at least one sensor signal of the at least one optical sensor 128 and for verifying the identity of the article 114 on the basis of the at least one sensor signal. Thus, as an example, the evaluation device 120 may be adapted for directly or indirectly comparing the at least one sensor signal with at least one predetermined sensor signal, in order to verify an identity of the article. Thus, as an example, by comparing the at least one sensor signal and/or at least one secondary sensor signal or item of information derived thereof with at least one predetermined sensor signal or item of information, the evaluation device 120 may be adapted for finding out whether the article 114 has a specific identity or not, or may be adapted to find out which identity, out of a plurality of predetermined potential identities, the article 114 actually has. The at least one predetermined sensor signal or predetermined item of information may be stored in at least one data storage 132 of the evaluation device 120 and/or may be retrieved via at least one interface 134. Thus, as an example, the evaluation device 120 may be adapted for retrieving information from at least one remote computer and/or remote data base, such as for verification purposes. The evaluation device 120 may further be adapted, in this embodiment or other embodiments, to provide a result of the verification process, such as via the at least one interface 134, via at least one other interface and/or via at least one display. As an example, at least one result of the verification process may be provided in an electronic format and/or in one or more of a visible, audible or tactile format. The result may be provided to another machine or computer and/or may be provided to a user. As an example, the verification device 110 may be part of a machine such as a cash box, a verification terminal for verifying credit cards or ATM-cards and/or of a teller machine.

The verification device 110, besides the components listed above, may comprise one or more further devices. Thus, as an example, the verification device 110 may comprise one or more transfer devices 136, adapted for transferring the light beam 122 onto the safety mark 124 and/or onto the detector 118, such as one or more lenses 138. Thus, the at least one transfer device 136 may fully or partially be located in a beam path of the light beam 122 before or after interaction with the safety mark 124. Further, the verification device 110 may comprise one or more filters 140 and/or other types of wavelength selective elements, which, again, may fully or partially be placed in the beam path of the light beam 122 before or after interaction with the safety mark 124. Further, the verification device 110 may comprise one or more polarizers 142, which, again, may be placed fully or partially in the beam path of the light beam 122 before or after interaction with the safety mark 124.

In FIG. 2, an alternative embodiment of the verification device 110 and the verification system 112 is shown. The embodiment shown in FIG. 2 widely corresponds to the embodiment of FIG. 1. Thus, with regard to most elements or devices of the setup shown in FIG. 2, reference may be made to the description of FIG. 1 above.

Contrarily to the setup shown in FIG. 1, the setup of FIG. 2 is a reflective setup. Thus, the safety mark 124, in the embodiment shown in FIG. 2, is a reflective safety mark, which fully or partially reflects the incident light beam 122. Thus, the illumination source 116 and the detector 118 are arranged on the same side of the article 114, which may allow for a simplified reading. Further, the safety mark 124 in this embodiment, may be embodied as an attachment to the article 114. As an example, the safety mark 124 may fully or partially be embodied as a sticker or a label attached to the article 114. Thus, while the set up of FIG. 1 is preferred for articles such as credit cards or ATM-cards which allow for a simple integration of the safety mark 124 into a body of the article 114, the setup shown in FIG. 2 is preferred for mass manufacturing, such as packaging of e.g. articles or other setups. Thus, the safety mark 124 may be attached to the object 114 by adhesives and/or may simply be printed onto the object 114. Thus, as an example, reflective safety marks 124 may be manufactured by mass manufacturing, via printing the safety marks 124 onto the article and/or labeling the articles 114 with one or more safety marks 124.

In FIG. 3, as outlined above, an exemplary embodiment of three different modifications of a light beam 122 by the safety mark 124, and the detection thereof by the detector 118, is shown. Thus, as an example, by interaction with the safety mark 124 as shown, e.g. in FIGS. 1 and/or 2, at least one beam property of the light beam 122 may be modified, such as by defocusing or focusing of the light beam 122. Thereby, as an example, focal points of the light beam 122 may be shifted by the safety mark 124. In the exemplary embodiment shown in FIG. 3, three different modifications of the light beam 122, leading to three different focal points F₁, F₂ and F₃, distributed along an optical axis 144, are shown. Consequently, due to the shift of the focal points, a beam cross-section, i.e. a diameter and/or an equivalent diameter of a light spot generated by the respective light beams 122 within the sensor region 130 of the optical sensors 128, is changed. In principle, a single optical sensor 128 exhibiting the above-mentioned FiP-effect is sufficient. However, in order to resolve ambiguities, a plurality of optical sensors 128 is preferred. Thus, a plurality of optical sensors 128 may be provided in a stack 146, stacked along the optical axis 144. Thereby, by evaluating the sensor signals of the optical sensors 128 of the stack 146, ambiguities may be resolved which may result from the fact that a beam cross-section at a distance z before and after a focal point is identical. By evaluating the sensor signals of stacked optical sensors 128, these ambiguities may be resolved, and the position of the focal point may actually be determined. Thus, the effect of the interaction of the safety mark 124 with the incident light beam 122, such as the effect on a shift of the focal point, may be determined by using the at least one optical sensor 128. Thus, by comparing e.g. the focal position with a predetermined focal position and/or by evaluating the focal position in any other way, a verification of the safety mark 124 and, thus, a verification of the article 114 may take place.

The above-mentioned FiP-effect, using the at least one safety mark 124, may be combined with other verification techniques. Thus, as shown in the exemplary embodiment of FIG. 1 and as may be implemented into other embodiments of the present invention, such as into the embodiment of FIG. 2, the verification system may further comprise an additional identifier 148 which may be one or both of attached to the article 114 and integrated into the article 114. As an example, the additional identifier 148 may be or may comprise an RFID-tag. The verification device 110 may further comprise at least one readout device 150, which may be connected to the evaluation device 120. As an example, the readout device 150 may be or may comprise an RFID-reader. The information read out from the additional identifier 148 may be used for the verification process, as an additional identification. Thus, as an example, the identification obtained from the additional identifier 148 may be compared with identification information obtained by using the above-mentioned FiP-effect and the above-mentioned effect of modification of the light beam 122 by the safety mark 124. Thus, the verification process may further be improved.

### LIST OF REFERENCE NUMBERS

110 verification device
112 verification system
114 article
116 illumination source
118 detector
120 evaluation device
122 light beam
124 safety mark
126 lens
128 optical sensor
130 sensor region
132 data storage
134 interface
136 transfer device
138 lens
140 filter
142 polarizer
144 optical axis
146 stack
148 additional identifier
150 readout device

1: A verification device for verifying the identity of an article, the verification device comprising:
at least one illumination source for illuminating at least one safety mark of the article with at least one light beam;
at least one detector adapted for detecting after an interaction of the light beam with the safety mark, the detector having at least one optical sensor, wherein the optical sensor has at least one sensor region, wherein the optical sensor is designed to generate at least one sensor signal in a manner dependent on an illumination of the sensor region by the light beam, wherein the sensor signal, given the same total power of the illumination, is dependent on a beam cross-section of the light beam in the sensor region; and
at least one evaluation device adapted for evaluating the sensor signal and for verifying the identity of the article on the basis of the sensor signal.

2: The verification device according to claim 1, wherein the evaluation device is adapted to determine at least one modification of at least one property of the light beam by evaluating the sensor signal, the modification being induced by the interaction of the light beam with the safety mark.

3: The verification device according to claim 2, wherein the evaluation device is adapted to compare the modification of the at least one property of the light beam with at least one predetermined modification.

4: The verification device according to claim 2, wherein the at least one property of the light beam modified by the interaction with the safety mark is selected from the group consisting of: a beam parameter of the light beam; a polarization of the light beam; a spectral property of the light beam; a focusing or a defocusing of the light beam; and a direction of propagation of the light beam.

5: The verification device according to claim 1, wherein the evaluation device is adapted to determine a beam cross-section of the light beam in the sensor region by evaluating the sensor signal and by taking into account known beam properties of the light beam.

6: The verification device according to claim 5, wherein the evaluation device is adapted to determine a change of the beam cross-section of the light beam induced by the interaction with the safety mark.

7: The verification device according to claim 1, wherein the optical sensor is an organic photodetector.

8: The verification device according to claim 1, wherein the optical sensor comprises at least one photosensitive layer setup, the photosensitive layer setup having at least one first electrode, at least one second electrode and at least one photovoltaic material sandwiched between the first electrode and the second electrode, wherein the photovoltaic material comprises at least one organic material.

9: The verification device according to claim 8, wherein the photosensitive layer setup comprises an n-semiconducting metal oxide, wherein the photosensitive layer setup further comprises at least one solid p-semiconducting organic material deposited on top of the n-semiconducting metal oxide.

10: The verification device according to claim 1, wherein the detector comprises a stack of at least two optical sensors.

11: A verification system for verifying the identity of an article, the verification system comprising at least one verification device according to claim 1, the verification system further comprising at least one article, the at least one article having at least one safety mark, the safety mark being adapted for interacting with the at least one light beam, the safety mark being adapted for modifying at least one property of the light beam when interacting with the light beam.

12: The verification system according to claim 11, wherein the safety mark comprises at least one element selected from the group consisting of: an element adapted for modifying at least one beam parameter of the light beam; a lens or lens system; a polarizer; a grating; an element for changing at least one spectral property of the light beam; and an element for changing a direction of propagation of the light beam.

13: The verification system according to claim 11, wherein the safety mark is one of a reflective safety mark and a transmissive safety mark.

14: The verification system according to claim 11, wherein the safety mark is adapted for generating a two-dimensional structure within the light beam, wherein the detector is adapted to at least partially determine the two-dimensional structure.

15: The verification system according to claim 11, wherein the article further comprises at least one additional identifier, wherein the verification device is adapted for reading out at least one item of verification information from the additional identifier and wherein the evaluation device is adapted to use the at least one item of verification information during verifying the identity of the article.

16: A method for verifying the identity of an article, the method comprising:
illuminating at least one safety mark of the article with at least one light beam by using at least one illumination source;
detecting the light beam after an interaction of the light beam with the safety mark by using a detector, the detector having at least one optical sensor, wherein the optical sensor has at least one sensor region, wherein the optical sensor is designed to generate at least one sensor signal in a manner dependent on an illumination of the sensor region by the light beam, wherein the sensor signal, given the same total power of the illumination, is dependent on a beam cross-section of the light beam in the sensor region; and
evaluating the sensor signal and verifying the identity of the article on the basis of the sensor signal, by using at least one evaluation device.

17. (canceled)

18: The verification device according to claim 4, wherein the property of the light beam is the beam parameter of the light beam, which is selected from the group consisting of a beam waist, a Rayleigh length, a focal position, a beam waist at a focal position, and a Gaussian beam parameter.

19: The verification device according to claim 4, wherein the property of the light beam is the spectral property of the light beam, which is at least one of a color of the light beam and a wavelength of the light beam.

20: The verification device according to claim 7, wherein the organic photodetector is an organic solar cell.

21: The verification device according to claim 20, wherein the organic solar cell is a dye sensitized organic solar cell.

22: The verification device according to claim 21, wherein the dye sensitized organic solar cell is a solid dye-sensitized organic solar cell.

23: The verification device according to claim 19, wherein the n-semiconducting metal oxide is a nano-porous n-semiconducting metal oxide.

24: The verification system according to claim 12, wherein the safety mark comprises the element adapted for modifying at least one beam parameter of the light beam, which is a beam parameter selected from the group consisting of a beam waist, a Rayleigh length, a focal position, a beam waist at a focal position, and a Gaussian beam parameter.

25: The verification system according to claim 12, wherein the safety mark comprises the lens or lens system, which is a Fresnel lens.

26: The verification system according to claim 12, wherein the safety mark comprises the element for changing at least one spectral property of the light beam, which is at least one element selected from the group consisting of a color filter and a wavelength selective reflective element.

27: The verification system according to claim 12, wherein the safety mark comprises the element for changing a direction of propagation of the light beam, which is a reflective element.

28: A method for verifying the identity of an article, the method comprising:
using an optical sensor, the optical sensor having at least one sensor region, wherein the optical sensor is designed to generate at least one sensor signal in a manner dependent on an illumination of the sensor region by a light beam, wherein the sensor signal, given the same total power of the illumination, is dependent on a beam cross-section of the light beam in the sensor region.
